(19) United States
(12) Patent Application Publication
(10) Pub. No.: US 2025/0351713 A1
(43) Pub. Date: Nov. 13, 2025

(54) DISPLAY DEVICE

(71) Applicant: Samsung Display Co., LTD., Yongin-si (KR)

(72) Inventor: Ju Hwa HA, Yongin-si (KR)

(21) Appl. No.: 19/026,160

(22) Filed: Jan. 16, 2025

(30) Foreign Application Priority Data
May 9, 2024 (KR) 10-2024-0061048

(51) Int. Cl. H10K 59/80

(52) U.S. Cl. CPC H10K 59/8791; H10K 59/878; H10K 59/879

(57) ABSTRACT

Provided is a display device including a display panel including a display module, and a window module above the display module and including a first polarizing film above the display module, a first phase retardation film above the first polarizing film, a window above the first phase retardation film, and a semi-transmissive reflective film above the window, and an optical module above the display panel, and including a first optical module including a first lens above the semi-transmissive reflective film, and a second optical module including a second phase retardation film above the first lens, a second polarizing film above the second phase retardation film, and a second lens above the second polarizing film.

### CROSS-REFERENCE TO RELATED APPLICATION

The present application claims priority to, and the benefit of, Korean Patent Application No. 10-2024-0061048, filed on May 9, 2024, in the Korean Intellectual Property Office, the entire disclosure of which is incorporated herein by reference.

### BACKGROUND

### 1. Field

The present disclosure relates to a display device.

### 2. Description of the Related Art

A head-mounted display (HMD) is an image display device that is worn on a user's head in the form of glasses or a helmet, and that forms a focus at a distance close to user's eyes in front of the user's eyes. The head-mounted display may implement virtual reality (VR) or augmented reality (AR).

The head-mounted display magnifies and displays an image displayed by a small display device using a plurality of lenses. Therefore, a display device applied to the head-mounted display needs to provide a relatively high-resolution image, for example, an image having a resolution of about 3000 pixels per inch (PPI) or more. To this end, an organic light-emitting diode on silicon (OLEDoS), which is a small organic light-emitting display device having a high resolution, has been used as the display device applied to the head-mounted display. The OLEDOS is a device that displays an image by placing organic light-emitting diodes (OLEDs) on a semiconductor wafer substrate including complementary metal oxide semiconductors (CMOSs).

### SUMMARY

Aspects of the present disclosure provide a display device in which the thickness of an optical module is reduced or minimized.

Aspects of the present disclosure also provide a display device with improved light output rate.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device including a display panel including a display module, and a window module above the display module and including a first polarizing film above the display module, a first phase retardation film above the first polarizing film, a window above the first phase retardation film, and a semi-transmissive reflective film above the window, and an optical module above the display panel, and including a first optical module including a first lens above the semi-transmissive reflective film, and a second optical module including a second phase retardation film above the first lens, a second polarizing film above the second phase retardation film, and a second lens above the second polarizing film.

The semi-transmissive reflective film may include a curved surface.

The window may include a curved first surface adjacent to the semi-transmissive reflective film.

A radius of curvature of the first surface may be about 100 mm or more.

The first polarizing film and the second polarizing film may include linear polarizing films, wherein a first polarization axis of the first polarizing film and a second polarization axis of the second polarizing film are substantially perpendicular.

The first polarizing film may include an absorption type polarizing film, wherein the second polarizing film includes a reflective polarizing film.

The display device may further include a third polarizing film above the second lens and having a third polarization axis extending in a direction parallel to the second polarization axis.

The third polarizing film may include an absorption type polarizing film.

The first phase retardation film and the second phase retardation film may include a quarter-wave plate, wherein a first optical axis of the first phase retardation film and a second optical axis of the second phase retardation film are offset in opposite directions.

The first lens and the second lens may include magnifying lenses.

The semi-transmissive reflective film may include layers in which first material layers having a first refractive index and second material layers, which have a second refractive index that is greater than the first refractive index, are alternately stacked, wherein a lowermost layer of the first and second material layers is one of the first material layers.

A number of the first material layers may be greater than a number of the second material layers.

The number of the first material layers may be greater than the number of the second material layers by one.

The first material layers may include silicon oxide, wherein the second material layers include titanium oxide.

A number of the first and second layers may be nine or more.

The first refractive index may be about 1.91 to about 1.93, wherein the second refractive index is about 3.45 to about 3.47.

The window module and the first optical module may be spaced apart, wherein the first optical module and the second optical module are spaced apart.

The display device may further include a coating film on a surface of the first optical module or a surface of the second optical module.

The display device may further include a third phase retardation film between the display module and the first polarizing film and including a quarter-wave plate.

The display panel may further include a semiconductor substrate, conductive layers sequentially stacked above the semiconductor substrate, a reflective electrode layer above the conductive layers, an insulating film covering at least a part of the reflective electrode layer, and light-emitting elements above the insulating film, and including a first electrode, a light-emitting stack, and a second electrode.

According to an aspect of the present disclosure, an electronic device includes a display device, the display device including, a display panel including a display module, and a window module above the display module and including, a first polarizing film above the display module, a first phase retardation film above the first polarizing film, a window above the first phase retardation film, and a semi-transmissive reflective film above the window, and an optical module above the display panel, and including, a first optical module including a first lens above the semi-transmissive reflective film, and a second optical module including a second phase retardation film above the first lens, a second polarizing film above the second phase retardation film, and a second lens above the second polarizing film.

In accordance with the display device according to one or more embodiments of the present disclosure, the thickness of the optical module may be reduced or minimized.

In accordance with the display device according to one or more embodiments of the present disclosure, the light output rate may be improved.

However, aspects according to the embodiments of the present disclosure are not limited to those above and various other aspects are incorporated herein.

### BRIEF DESCRIPTION OF THE DRAWINGS

The above and other aspects of the present disclosure will become more apparent by describing in detail embodiments thereof with reference to the attached drawings, in which:

FIG. 1 is an exploded perspective view showing a display device according to one or more embodiments;

FIG. 2 is a block diagram illustrating a display device according to one or more embodiments;

FIG. 3 is an equivalent circuit diagram of a first sub-pixel according to one or more embodiments;

FIG. 4 is a plan view illustrating an example of a display panel according to one or more embodiments;

FIGS. 5 and 6 are plan views illustrating embodiments of the display area of FIG. 4;

FIG. 7 is a cross-sectional view illustrating an example of a display panel taken along line X1-X1′ of FIG. 5;

FIGS. 8 and 9 are cross-sectional views of a display device according to one or more embodiments;

FIG. 10 is a schematic diagram for explaining a path of light and a polarization state of light emitted from a display device according to one or more embodiments;

FIG. 11 is a cross-sectional view illustrating a stacked structure of a semi-transparent reflective film according to one or more embodiments;

FIG. 12 is a cross-sectional view illustrating a display device according to one or more other embodiments;

FIG. 13 is a cross-sectional view illustrating a display device according to still one or more other embodiments;

FIG. 14 is a cross-sectional view illustrating a display device according to still one or more other embodiments;

FIG. 15 is a perspective view illustrating a head-mounted display device according to one or more embodiments;

FIG. 16 is an exploded perspective view illustrating an example of the head-mounted display device of FIG. 15; and

FIG. 17 is a perspective view illustrating a head-mounted display device according to one or more other embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

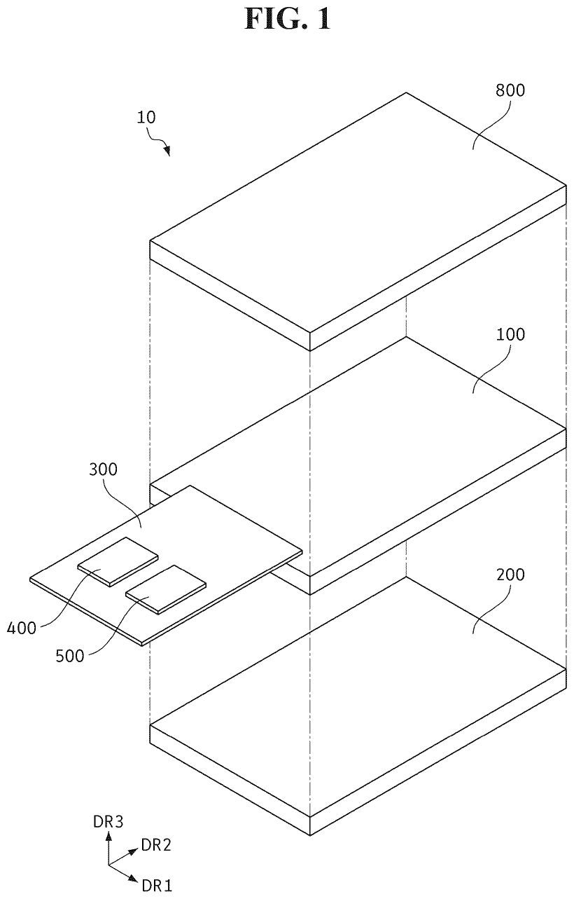

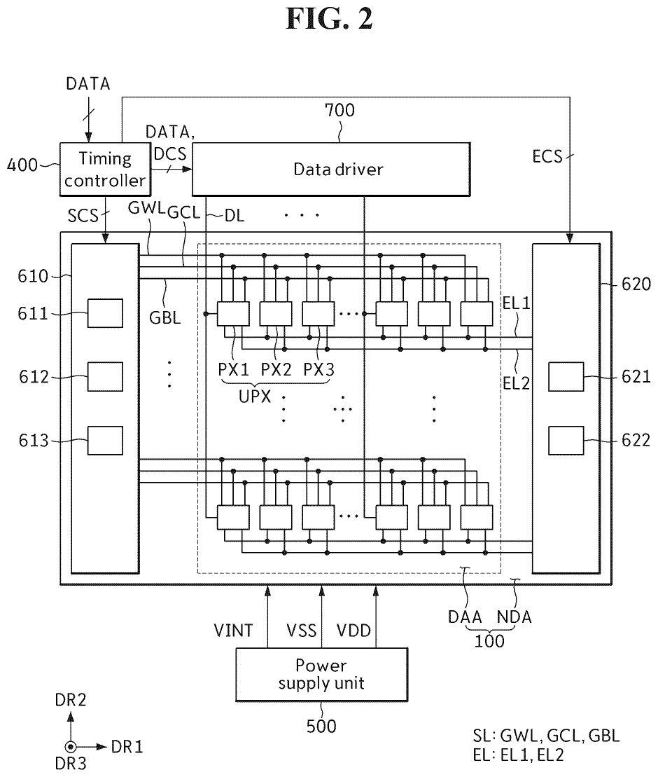

FIG. 1 is an exploded perspective view showing a display device according to one or more embodiments. FIG. 2 is a block diagram illustrating a display device according to one or more embodiments.

Referring to FIGS. 1 and 2, a display device 10 according to one or more embodiments may be a device displaying a moving image or a still image. The display device 10 according to one or more embodiments may be applied to portable electronic devices, such as a mobile phone, a smartphone, a tablet personal computer, a mobile communication terminal, an electronic organizer, an electronic book, a portable multimedia player (PMP), a navigation system, an ultra-mobile PC (UMPC) or the like. For example, the display device 10 according to one or more embodiments may be applied as a display unit of a television, a laptop, a monitor, a billboard, or an Internet-of-Things (IoT) terminal. Alternatively, the display device 10 according to one or more embodiments may be applied to a smart watch, a watch phone, a head-mounted display (HMD) for implementing virtual reality and augmented reality, and the like.

The display device 10 according to one or more embodiments may include a display panel 100, a heat dissipation layer 200, a circuit board 300, a timing control circuit 400, a power supply circuit 500, and an optical module 800.

The display panel 100 may have a planar shape similar to a quadrilateral shape. For example, the display panel 100 may have a planar shape similar to a quadrilateral shape, having a short side of a first direction DR1, and a long side of a second direction DR2 crossing the first direction DR1. In the display panel 100, a corner where a short side in the first direction DR1 and a long side in the second direction DR2 meet may be right-angled or rounded with a curvature (e.g., predetermined curvature). The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the present specification is not limited thereto.

In the illustrated figure, the first direction DR1 and the second direction DR2 cross each other as horizontal directions. For example, the first direction DR1 and the second direction DR2 may be orthogonal to each other. In addition, a third direction DR3 crosses the first direction DR1 and the second direction DR2, and they may be, for example, substantially perpendicular directions orthogonal to each other. Unless otherwise defined, in the present specification, directions indicated by arrows of the first to third directions DR1, DR2, and DR3 may be referred to as one side, and the opposite directions thereto may be referred to as the other side. Also, the terms “above,” “upper side,” “upper portion,” “top,” and “top surface,” as used herein, refer to a direction indicated by an arrow in the drawing in the third direction DR3 based on the drawings, and the terms “below,” “lower side,” “lower portion,” “bottom,” and “bottom surface,” as used herein, refer to a direction opposite to the direction indicated by the arrow in the third direction DR3 based on the drawings.

The display panel 100 may include a display area DAA displaying an image and a non-display area NDA not displaying an image as shown in FIG. 2.

The display area DAA may include a plurality of pixels PX, a plurality of scan lines SL, a plurality of emission control lines EL, and a plurality of data lines DL.

The plurality of pixels PX may be arranged in a matrix form in the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being located in the first direction DR1.

The plurality of scan lines SL may include a plurality of write scan lines GWL, a plurality of control scan lines GCL, and a plurality of bias scan lines GBL. The plurality of emission control lines EL may include a plurality of first emission control lines EL1 and a plurality of second emission control lines EL2.

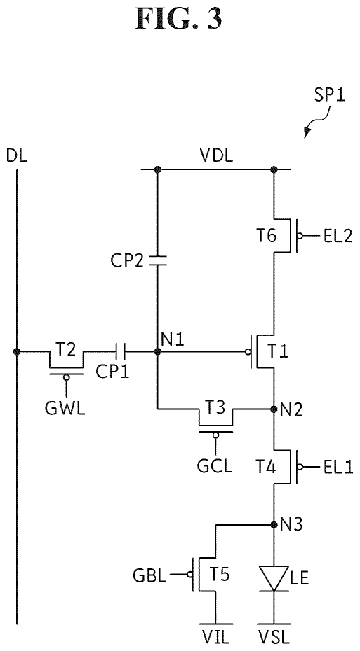

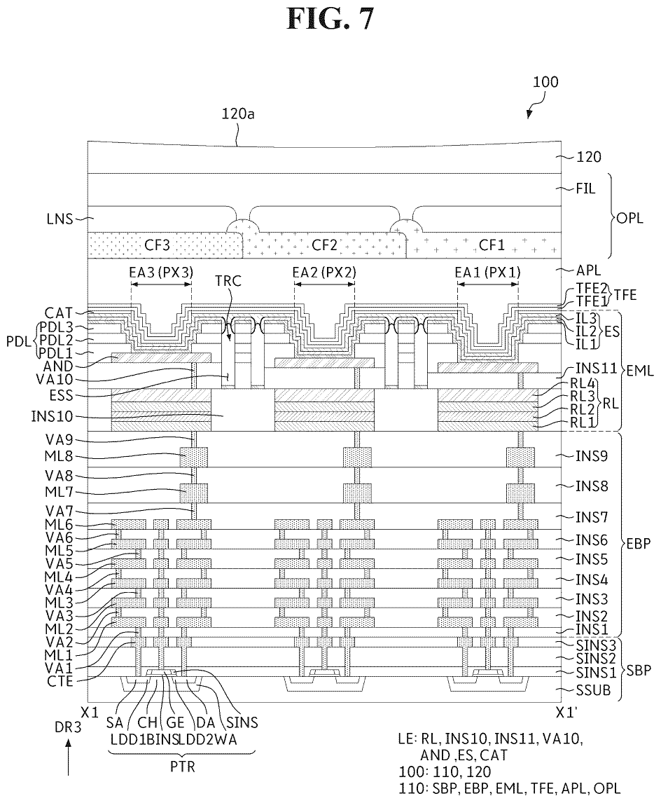

The plurality of pixels PX may include a plurality of sub-pixels SP1, SP2, and SP3. The plurality of sub-pixels SP1, SP2, and SP3 may include a plurality of pixel transistors as shown in FIG. 3 to be described later, and the plurality of pixel transistors may be formed by a semiconductor process and located on a semiconductor substrate SSUB (See FIG. 7). For example, the plurality of pixel transistors of a data driver 700 may be formed of complementary metal oxide semiconductor (CMOS).

Each of the plurality of sub-pixels SP1, SP2, and SP3 may be connected to any one write scan line GWL among the plurality of write scan lines GWL, any one control scan line GCL among the plurality of control scan lines GCL, any one bias scan line GBL among the plurality of bias scan lines GBL, any one first emission control line EL1 among the plurality of first emission control lines EL1, any one second emission control line EL2 among the plurality of second emission control lines EL2, and any one data line DL among the plurality of data lines DL. Each of the plurality of sub-pixels SP1, SP2, and SP3 may receive a data voltage of the data line DL in response to a write scan signal of the write scan line GWL, and emit light from the light-emitting element according to the data voltage.

The non-display area NDA may include a scan driver 610, an emission driver 620, and the data driver 700.

The scan driver 610 may include a plurality of scan transistors, and the emission driver 620 includes a plurality of light-emitting transistors. The plurality of scan transistors and the plurality of light-emitting transistors may be formed through a semiconductor process, and may be located on the semiconductor substrate SSUB (see FIG. 7). For example, the plurality of scan transistors and the plurality of light-emitting transistors may be formed of CMOS. Although it is illustrated in FIG. 2 that the scan driver 610 is located on the left side of the display area DAA and the emission driver 620 is located on the right side of the display area DAA, the present disclosure is not limited thereto. For example, the scan driver 610 and the emission driver 620 may be located on both the left side and the right side of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan-timing control signal SCS from the timing control circuit 400. The write scan signal output unit 611 may generate write scan signals according to the scan-timing control signal SCS of the timing control circuit 400, and may output them sequentially to the write scan lines GWL. The control scan signal output unit 612 may generate control scan signals in response to the scan-timing control signal SCS, and may sequentially output them to the control scan lines GCL. The bias scan signal output unit 613 may generate bias scan signals according to the scan-timing control signal SCS, and may output them sequentially to bias scan lines EBL.

The emission driver 620 may include a first emission control driver 621 and a second emission control driver 622. Each of the first emission control driver 621 and the second emission control driver 622 may receive the emission-timing control signal ECS from the timing control circuit 400. The first emission control driver 621 may generate first emission control signals according to the emission-timing control signal ECS, and may sequentially output them to the first emission control lines EL1. The second emission control driver 622 may generate second emission control signals according to the emission-timing control signal ECS, and may sequentially output them to the second emission control lines EL2.

The data driver 700 may include a plurality of data transistors, and the plurality of data transistors may be formed through a semiconductor process, and located on the semiconductor substrate SSUB (see FIG. 7). For example, the plurality of data transistors may be formed of CMOS.

The data driver 700 may receive digital video data DATA and a data-timing control signal DCS from the timing control circuit 400. The data driver 700 may convert the digital video data DATA into analog data voltages according to the data-timing control signal DCS, and may output the analog data voltages to the data lines DL. In this case, the sub-pixels SP1, SP2, and SP3 are selected by the write scan signal of the scan driver 610, and data voltages may be supplied to the selected sub-pixels SP1, SP2, and SP3.

The heat dissipation layer 200 may overlap the display panel 100 in the third direction DR3, which is the thickness direction of the display panel 100. The heat dissipation layer 200 may be located on one surface of the display panel 100, for example, on the rear surface thereof. The heat dissipation layer 200 may serve to dissipate heat generated from the display panel 100. The heat dissipation layer 200 may include a metal layer having high thermal conductivity, such as graphite, silver (Ag), copper (Cu), or aluminum (Al).

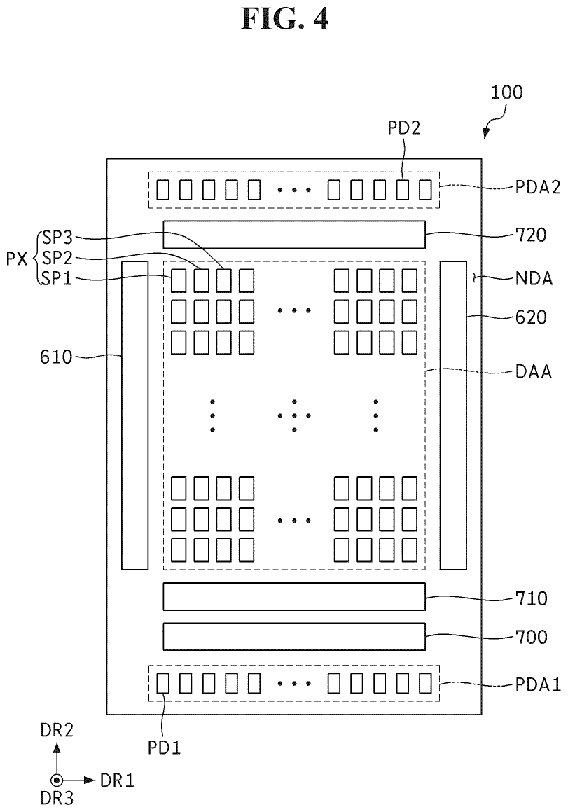

The circuit board 300 may be electrically connected to a plurality of first pads PD1 (see FIG. 4) of a first pad portion PDA1 (see FIG. 4) of the display panel 100 by using a conductive adhesive member, such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be located on the rear surface of the display panel 100 and/or the rear surface of the heat dissipation layer 200. One end of the circuit board 300 may be an opposite end of the other end of the circuit board 300 connected to the plurality of first pads PD1 (see FIG. 4) of the first pad portion PDA1 (see FIG. 4) of the display panel 100 by using a conductive adhesive member.

The timing control circuit 400 may receive externally supplied digital video data and timing signals. The timing control circuit 400 may generate the scan-timing control signal SCS, the emission-timing control signal ECS, and the data-timing control signal DCS for controlling the display panel 100 in response to the timing signals. The timing control circuit 400 may output the scan-timing control signal SCS to the scan driver 610, and may output the emission-timing control signal ECS to the emission driver 620. The timing control circuit 400 may output the digital video data and the data-timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (IC) and attached to one surface of the circuit board 300. In this case, the scan-timing control signal SCS, the emission-timing control signal ECS, digital video data DATA, and the data-timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

Alternatively, each of the timing control circuit 400 and the power supply circuit 500 may be located in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed through a semiconductor process, and located on the semiconductor substrate SSUB (see FIG. 7). For example, the plurality of timing transistors and the plurality of power transistors may be formed of CMOS. Each of the timing control circuit 400 and the power supply circuit 500 may be located between the data driver 700 and the first pad portion PDA1 (see FIG. 4).

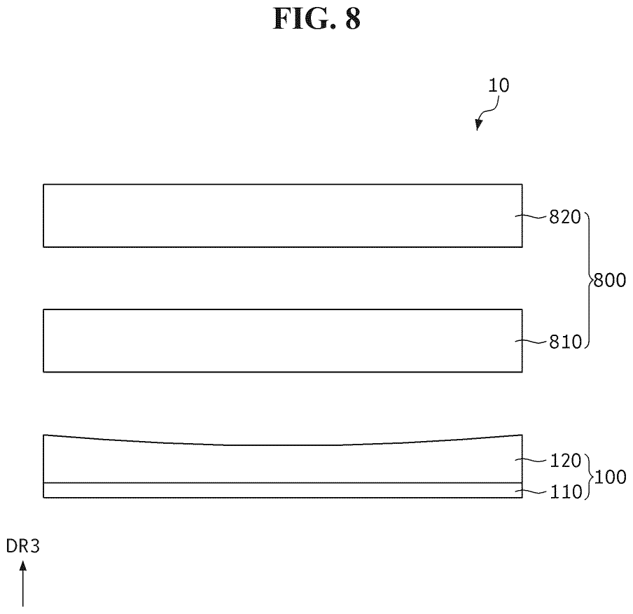

The optical module 800 may be located on the display panel 100. The optical module 800 may adjust the path and polarization state of light emitted from the display panel 100. The optical module 800 may implement folded optics that folds an optical path. The optical module 800 will be described later with reference to FIG. 8 and the like.

FIG. 3 is an equivalent circuit diagram of a first sub-pixel according to one or more embodiments.

Referring to FIG. 3 in addition to FIGS. 1 and 2, the first sub-pixel SP1 may be connected to the write scan line GWL, the control scan line GCL, the bias scan line GBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

The first sub-pixel SP1 may include a plurality of transistors T1 to T6, a light-emitting element LE, a first capacitor CP1, and a second capacitor CP2.

The light-emitting element LE may emit light in response to a driving current (source-drain current) flowing through the channel of a first transistor T1. A light emission amount of the light-emitting element LE may be proportional to the driving current. The light-emitting element LE may be located between a fourth transistor T4 and the first driving voltage line VSL. The first electrode of the light-emitting element LE may be connected to the drain electrode of the fourth transistor T4, and the second electrode thereof may be connected to the first driving voltage line VSL. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer located between the first electrode and the second electrode, but the present specification is not limited thereto. For example, the light-emitting element LE may be an inorganic light-emitting element including a first electrode, a second electrode, and an inorganic semiconductor located between the first electrode and the second electrode, and the light-emitting element LE may be, for example, a micro light-emitting diode.

The first transistor T1 may be a driving transistor that controls a driving current flowing between the source electrode and the drain electrode thereof according to a voltage applied to the gate electrode thereof. The first transistor T1 may include a gate electrode connected to a first node N1, a source electrode connected to the drain electrode of a sixth transistor T6, and a drain electrode connected to a second node N2.

A second transistor T2 may be located between one electrode of the first capacitor CP1 and the data line DL. The second transistor T2 may be turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 may include a gate electrode connected to the write scan line GWL, a source electrode connected to the data line DL, and a drain electrode connected to the one electrode of the first capacitor CP1.

A third transistor T3 may be located between the first node N1 and the second node N2. The third transistor T3 may be turned on by the write control signal of the control scan line GCL to connect the first node N1 to the second node N2. For this reason, because the gate electrode and the source electrode of the first transistor T1 are connected, the first transistor T1 may operate like a diode. The third transistor T3 may include a gate electrode connected to the control scan line GCL, a source electrode connected to the second node N2, and a drain electrode connected to the first node N1.

The fourth transistor T4 may be connected between the second node N2 and a third node N3. The fourth transistor T4 may be turned on by the first emission control signal of the first emission control line EL1 to connect the second node N2 to the third node N3. Accordingly, the driving current of the first transistor T1 may be supplied to the light-emitting element LE. The fourth transistor T4 may include a gate electrode connected to the first emission control line EL1, a source electrode connected to the second node N2, and a drain electrode connected to the third node N3.

A fifth transistor T5 may be located between the third node N3 and the third driving voltage line VIL. The fifth transistor T5 may be turned on by the bias scan signal of the bias scan line GBL to connect the third node N3 to the third driving voltage line VIL. Accordingly, the third driving voltage VINT of the third driving voltage line VIL may be applied to the first electrode of the light-emitting element LE. The fifth transistor T5 may include a gate electrode connected to the bias scan line GBL, a source electrode connected to the third node N3, and a drain electrode connected to the third driving voltage line VIL.

The sixth transistor T6 may be located between the source electrode of the first transistor T1 and the second driving voltage line VDL. The sixth transistor T6 may be turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor CP1 may be located between the first node N1 and the drain electrode of the second transistor T2. The first capacitor CP1 may include one electrode connected to the drain electrode of the second transistor T2 and the other electrode connected to the first node N1.

The second capacitor CP2 may be located between the gate electrode of the first transistor T1 and the second driving voltage line VDL. The second capacitor CP2 may include one electrode connected to the gate electrode of the first transistor T1 and the other electrode connected to the second driving voltage line VDL.

The first node N1 may be a junction between the gate electrode of the first transistor T1, the drain electrode of the third transistor T3, the other electrode of the first capacitor CP1, and the one electrode of the second capacitor CP2. The second node N2 may be a junction between the drain electrode of the first transistor T1, the source electrode of the third transistor T3, and the source electrode of the fourth transistor T4. The third node N3 may be a junction between the drain electrode of the fourth transistor T4, the source electrode of the fifth transistor T5, and the first electrode of the light-emitting element LE.

Each of the first to sixth transistors T1 to T6 may be a metal-oxide-semiconductor field effect transistor (MOSFET). For example, each of the first to sixth transistors T1 to T6 may be a P-type MOSFET, but the present specification is not limited thereto. Each of the first to sixth transistors T1 to T6 may be an N-type MOSFET. Alternatively, one or more of the first to sixth transistors T1 to T6 may be P-type MOSFETs, and each of the remaining transistor(s) may be an N-type MOSFET.

Although it is illustrated in FIG. 3 that the first sub-pixel SP1 includes six transistors T1 to T6 and two capacitors C1 and C2, the equivalent circuit diagram of the first sub-pixel SP1 is not limited to that shown in FIG. 3. For example, the number of the transistors and the number of the capacitors of the first sub-pixel SP1 may be changed in various ways.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 is omitted in the present specification.

FIG. 4 is a plan view illustrating an example of a display panel according to one or more embodiments.

Referring to FIG. 4, the display area DAA of the display panel 100 according to one or more embodiments may include the plurality of pixels PX arranged in a matrix form. The non-display area NDA of the display panel 100 according to one or more embodiments may include the scan driver 610, the emission driver 620, the data driver 700, a first distribution circuit 710, a second distribution circuit 720, the first pad portion PDA1, and a second pad portion PDA2.

The scan driver 610 may be located on the first side of the display area DAA, and the emission driver 620 may be located on the second side of the display area DAA. For example, the scan driver 610 may be located on the other side of the display area DAA in the first direction DR1, and the emission driver 620 may be located on one side of the display area DAA in the first direction DR1. That is, the scan driver 610 may be located on the left side of the display area DAA, and the emission driver 620 may be located on the right side of the display area DAA.

The first pad portion PDA1 may include the plurality of first pads PD1 connected to pads or bumps of the circuit board 300 through a conductive adhesive member. The first pad portion PDA1 may be located on the third side of the display area DAA. For example, the first pad portion PDA1 may be located on the other side of the display area DAA in the second direction DR2. That is, the first pad portion PDA1 may be located on the lower side of the display area DAA.

The first pad portion PDA1 may be located outside the data driver 700 in the second direction DR2. That is, the first pad portion PDA1 may be located closer to the edge of the display panel 100 than the data driver 700.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection.

The circuit board for inspection may be a printed circuit board made of a rigid material or a flexible printed circuit board made of a flexible material.

The first distribution circuit 710 may distribute data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be located on the third side of the display area DAA of the display panel 100. For example, the first distribution circuit 710 may be located on the other side of the display area DAA in the second direction DR2. That is, the first distribution circuit 710 may be located on the lower side of the display area DAA.

The second distribution circuit 720 may distribute signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be located on the fourth side of the display area DAA of the display panel 100. For example, the second distribution circuit 720 may be located on one side of the display area DAA in the second direction DR2. That is, the second distribution circuit 720 may be located on the upper side of the display area DAA.

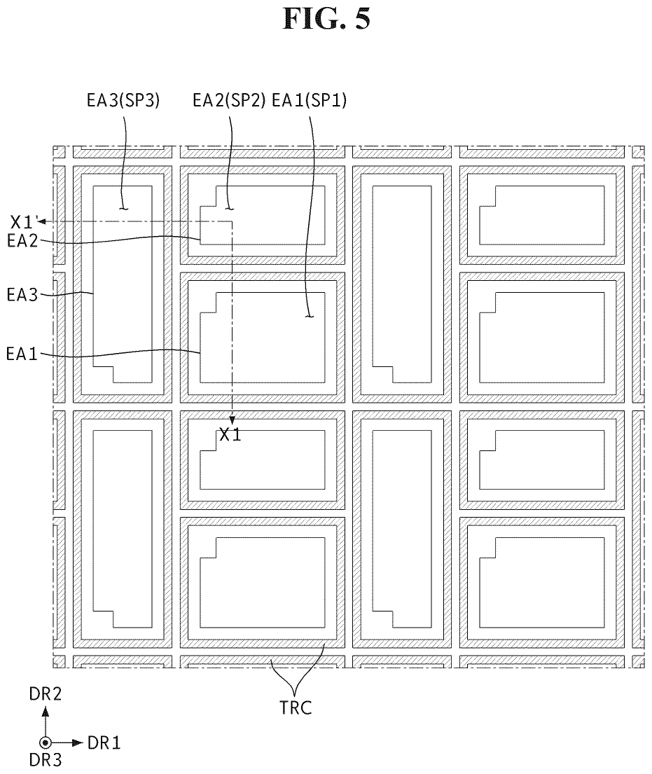

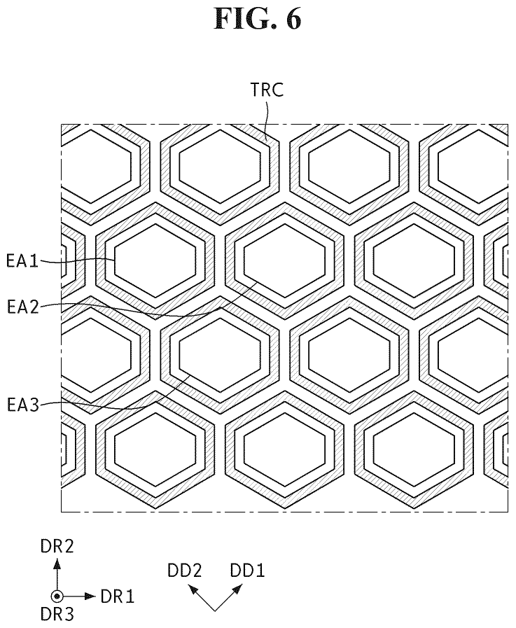

FIGS. 5 and 6 are plan views illustrating embodiments of the display area of FIG. 4.

Referring to FIGS. 5 and 6, each of the pixels PX may include the first emission area EA1 that is an emission area of the first sub-pixel SP1, the second emission area EA2 that is an emission area of the second sub-pixel SP2, and the third emission area EA3 that is an emission area of the third sub-pixel SP3.

In some embodiments, as shown in FIGS. 5 and 6, the first emission area EA1, the second emission area EA2, and the third emission area EA3 may have, in plan view, a hexagonal shape formed of six straight lines, but the present specification is not limited thereto. The first emission area EA1, the second emission area EA2, and the third emission area EA3 may have a polygonal shape other than a hexagon, a circular shape, an elliptical shape, or an atypical shape in plan view.

In some embodiments, as shown in FIG. 5, the maximum length of the third emission area EA3 in the first direction DR1 may be less than the maximum length of the first emission area EA1 in the first direction DR1, and less than the maximum length of the second emission area EA2 in the first direction DR1. The maximum length of the first emission area EA1 in the first direction DR1 and the maximum length of the second emission area EA2 in the first direction DR1 may be substantially the same.

In some embodiments, as shown in FIG. 5, the maximum length of the third emission area EA3 in the second direction DR2 may be greater than the maximum length of the first emission area EA1 in the second direction DR2, and greater than the maximum length of the second emission area EA2 in the second direction DR2. The maximum length of the first emission area EA1 in the second direction DR2 may be greater than the maximum length of the second emission area EA2 in the second direction DR2.

In one or more embodiments, as shown in FIG. 5, the first emission area EA1 and the second emission area EA2 in each of the plurality of pixels PX may be adjacent to each other in the second direction DR2. The first emission area EA1 and the third emission area EA3 may be adjacent to each other in the first direction DR1. The second emission area EA2 and the third emission area EA3 may be adjacent to each other in the first direction DR1. The area of the first emission area EA1, the area of the second emission area EA2, and the area of the third emission area EA3 may be different.

In one or more other embodiments, as shown in FIG. 6, in each of the plurality of pixels PX, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2.

In the illustrated drawing, the first diagonal direction DD1 crosses each of the first direction DR1 and the second direction DR2 as horizontal directions. For example, the first diagonal direction DD1 may be a direction inclined by about 45 degrees with respect to the first direction DR1 and the second direction DR2, but the present disclosure is not limited thereto. The second diagonal direction DD2 crosses each of the first direction DR1 and the second direction DR2 as horizontal directions. For example, the second diagonal direction DD2 may be a direction inclined by about 45 degrees with respect to the opposite direction of the first direction DR1 and the second direction DR2, but the present disclosure is not limited thereto. The second diagonal direction DD2 may be a direction substantially perpendicular to the first diagonal direction DD1.

The first emission area EA1 may emit light of a first color, the second emission area EA2 may emit light of a second color, and the third emission area EA3 may emit light of a third color. Here, the light of the first color may be light of a red wavelength band, the light of the second color may be light of a green wavelength band, and the light of the third color may be light of a blue wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band is a wavelength band of light whose main peak wavelength may be in the range of about 600 nm to about 750 nm.

It is shown in FIGS. 5 and 6 that each of the plurality of pixels PX includes three emission areas EA1, EA2, and EA3, but the present specification is not limited thereto. That is, each of the plurality of pixels PX may include four or more emission areas.

In addition, the shape and disposition of the emission areas of the plurality of pixels PX are not limited to those illustrated in FIGS. 5 and 6. For example, the emission areas of the plurality of pixels PX may be located in a stripe structure in which the emission areas are arranged in the first direction DR1, a PenTile® structure (PenTile® being a registered trademark of Samsung Display Co., Ltd., Republic of Korea) in which the emission areas are arranged in a diamond shape, or a hexagonal structure in which the emission areas having, in plan view, a hexagonal shape are arranged side by side as shown in FIG. 6.

FIG. 7 is a cross-sectional view illustrating an example of a display panel taken along line X1-X1′ of FIG. 5.

Referring to FIG. 7, the display panel 100 may include a display module 110 and a window module 120. The display panel 100 may include a semiconductor backplane SBP, a light-emitting element backplane EBP, a display element layer EML, an encapsulation layer TFE, and an optical layer OPL.

The semiconductor backplane SBP may include the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 (see FIG. 4) described with reference to FIG. 4.

The semiconductor substrate SSUB may be a silicon substrate, a germanium substrate, or a silicon-germanium substrate. The semiconductor substrate SSUB may be a substrate doped with a first type impurity. A plurality of well regions WA may be located on the top surface of the semiconductor substrate SSUB (as used herein, “located on” may mean “above”). The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA may include a source region SA corresponding to the source electrode of the pixel transistor PTR, a drain region DA corresponding to the drain electrode thereof, and a channel region CH located between the source region SA and the drain region DA.

A lower insulating film BINS may be located between a gate electrode GE and the well region WA. A side insulating film SINS may be located on the side surface of the gate electrode GE. The side insulating film SINS may be located on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be located on one side of the gate electrode GE, and the drain region DA may be located on the other side of the gate electrode GE.

Each of the plurality of well regions WA may further include a first low-concentration impurity region LDD1 located between the channel region CH and the source region SA, and a second low-concentration impurity region LDD2 located between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase so that punch-through and hot carrier phenomena that might be caused by a short channel may be reduced or prevented.

A first semiconductor insulating film SINS1 may be located on the semiconductor substrate SSUB. The first semiconductor insulating film SINS1 may be formed of silicon carbonitride (SiCN) or a silicon oxide (SiOx)-based inorganic film, but the present specification is not limited thereto.

A second semiconductor insulating film SINS2 may be located on the first semiconductor insulating film SINS1. The second semiconductor insulating film SINS2 may be formed of a silicon oxide (SiOx)-based inorganic film, but the present specification is not limited thereto.

The plurality of contact terminals CTE may be located on the second semiconductor insulating film SINS2. Each of the plurality of contact terminals CTE may be connected to any one of the gate electrode GE, the source region SA, or the drain region DA of each of the pixel transistors PTR through holes penetrating the first semiconductor insulating film SINS1 and the second semiconductor insulating film SINS2. The plurality of contact terminals CTE may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them.

A third semiconductor insulating film SINS3 may be located on a side surface of each of the plurality of contact terminals CTE. The top surface of each of the plurality of contact terminals CTE may be exposed without being covered by the third semiconductor insulating film SINS3. The third semiconductor insulating film SINS3 may be formed of a silicon oxide (SiOx)-based inorganic film, but the present specification is not limited thereto.

The semiconductor substrate SSUB may be replaced with a glass substrate or a polymer resin substrate, such as polyimide. In this case, thin film transistors may be located on the glass substrate or the polymer resin substrate. The glass substrate may be a rigid substrate that does not bend, and the polymer resin substrate may be a flexible substrate that can be bent or curved.

The light-emitting element backplane EBP may include a plurality of conductive layers ML1 to ML8, a plurality of vias VA1 to VA9, and a plurality of insulating films INS1 to INS9.

The first to eighth conductive layers ML1 to ML8 may serve to connect the plurality of contact terminals CTE exposed from the semiconductor backplane SBP to thereby implement the pixel circuit of the first sub-pixel SP1 shown in FIG. 4. For example, the first to sixth transistors T1 to T6 are merely located on the semiconductor backplane SBP, and the connection line of the first to sixth transistors T1 to T6 and the first capacitor C1 and the second capacitor C2 may be located in the first to eighth conductive layers ML1 to ML8. In addition, a connection portion between the drain region corresponding to the drain electrode of the fourth transistor T4, the source region corresponding to the source electrode of the fifth transistor T5, and the first electrode of the light-emitting element LE may also be located in the first to eighth conductive layers ML1 to ML8.

The first insulating film INS1 may be located on the semiconductor backplane SBP. Each of the first vias VA1 may penetrate the first insulating film INS1 to be connected to the contact terminal CTE exposed from the semiconductor backplane SBP. Each of the first conductive layers ML1 may be located on the first insulating film INS1 and may be connected to the first via VA1.

The second insulating film INS2 may be located on the first insulating film INS1 and the first conductive layers ML1. Each of the second vias VA2 may penetrate the second insulating film INS2, and may be connected to the exposed first conductive layer ML1. Each of the second conductive layers ML2 may be located on the second insulating film INS2 and may be connected to the second via VA2.

The third insulating film INS3 may be located on the second insulating film INS2 and the second conductive layers ML2. Each of the third vias VA3 may penetrate the third insulating film INS3, and may be connected to the exposed second conductive layer ML2. Each of the third conductive layers ML3 may be located on the third insulating film INS3 and may be connected to the third via VA3.

A fourth insulating film INS4 may be located on the third insulating film INS3 and the third conductive layers ML3. Each of the fourth vias VA4 may penetrate the fourth insulating film INS4, and may be connected to the exposed third conductive layer ML3. Each of the fourth conductive layers ML4 may be located on the fourth insulating film INS4 and may be connected to the fourth via VA4.

A fifth insulating film INS5 may be located on the fourth insulating film INS4 and the fourth conductive layers ML4. Each of the fifth vias VA5 may penetrate the fifth insulating film INS5, and may be connected to the exposed fourth conductive layer ML4. Each of the fifth conductive layers ML5 may be located on the fifth insulating film INS5 and may be connected to the fifth via VA5.

A sixth insulating film INS6 may be located on the fifth insulating film INS5 and the fifth conductive layers ML5. Each of the sixth vias VA6 may penetrate the sixth insulating film INS6, and may be connected to the exposed fifth conductive layer ML5. Each of the sixth conductive layers ML6 may be located on the sixth insulating film INS6 and may be connected to the sixth via VA6.

A seventh insulating film INS7 may be located on the sixth insulating film INS6 and the sixth conductive layers ML6. Each of the seventh vias VA7 may penetrate the seventh insulating film INS7, and may be connected to the exposed sixth conductive layer ML6. Each of the seventh conductive layers ML7 may be located on the seventh insulating film INS7 and may be connected to the seventh via VA7.

An eighth insulating film INS8 may be located on the seventh insulating film INS7 and the seventh conductive layers ML7. Each of the eighth vias VA8 may penetrate the eighth insulating film INS8, and may be connected to the exposed seventh conductive layer ML7. Each of the eighth conductive layers ML8 may be located on the eighth insulating film INS8 and may be connected to the eighth via VA8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. First to eighth insulating films INS1 to INS8 may be formed of a silicon oxide (SiOx)-based inorganic film, but the present specification is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å. For example, the thickness of each of the second conductive layer ML2, the third conductive layer ML3, the fourth conductive layer ML4, the fifth conductive layer ML5, and the sixth conductive layer ML6 may be approximately 1440 Å. For example, the thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9000 Å, and the thickness of each of the seventh via VA7 and the eighth via VA8 may be approximately 6000 Å.

A ninth insulating film INS9 may be located on the eighth insulating film INS8 and the eighth conductive layer ML8. The ninth insulating film INS9 may be formed of a silicon oxide (SiOx)-based inorganic film, but the present specification is not limited thereto.

Each of the ninth vias VA9 may penetrate the ninth insulating film INS9, and may be connected to the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. The thickness of the ninth via VA9 may be approximately 16500 Å.

The display element layer EML may be located on the light-emitting element backplane EBP. The display element layer EML may include light-emitting elements LE each including a reflective electrode layer RL, tenth and eleventh insulating films INS10 and INS11, a tenth via VA10, a first electrode AND, a light-emitting stack IL, and a second electrode CAT. The display element layer EML may also include a pixel-defining film PDL, and a plurality of trenches TRC.

The reflective electrode layer RL may be located on the ninth insulating film INS9. The reflective electrode layer RL may include at least one reflective electrode RL1, RL2, RL3, and RL4. For example, the reflective electrode layer RL may include first to fourth reflective electrodes RL1, RL2, RL3, and RL4 as shown in FIG. 7, but is not limited thereto.

Each of the first reflective electrodes RL1 may be located on the ninth insulating film INS9, and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the first reflective electrodes RL1 may include titanium nitride (TiN).

Each of the second reflective electrodes RL2 may be located on a corresponding first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the second reflective electrodes RL2 may include aluminum (Al).

Each of the third reflective electrodes RL3 may be located on a corresponding second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the third reflective electrodes RL3 may include titanium nitride (TiN).

Each of the fourth reflective electrodes RL4 may be respectively located on a corresponding third reflective electrode RL3. The fourth reflective electrodes RL4 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the fourth reflective electrodes RL4 may include titanium (Ti).

Because the second reflective electrode RL2 is an electrode that substantially reflects light from the light-emitting elements LE, the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 may be approximately 100 Å, and the thickness of the second reflective electrode RL2 may be approximately 850 Å.

The tenth insulating film INS10 may be located on the ninth insulating film INS9. The tenth insulating film INS10 may be located between the reflective electrode layers RL adjacent to each other in a horizontal direction. The tenth insulating film INS10 may be formed of a silicon oxide (SiOx)-based inorganic film, but the present specification is not limited thereto. In some embodiments, the tenth insulating film INS10 may be located not only between the reflective electrode layers RL but also on the reflective electrode layer RL.

The eleventh insulating film INS11 may be located on the tenth insulating film INS10 and the reflective electrode layer RL. The eleventh insulating film INS11 may be formed of a silicon oxide (SiOx)-based inorganic film, but the present specification is not limited thereto. The tenth insulating film INS10 and the eleventh insulating film INS11 may be an optical auxiliary layer through which light reflected by the reflective electrode layer RL passes, among light emitted from the light-emitting elements LE.

In some embodiments, in at least any one sub-pixel among the first sub-pixel SP1, the second sub-pixel SP2, and the third sub-pixel SP3, to adjust the resonance distance of light emitted from the light-emitting elements LE, the total thickness of the insulating film located between the first electrode AND and the reflective electrode layer RL may be different in the first sub-pixel SP1, the second sub-pixel SP2, and the third sub-pixel SP3.

In one or more embodiments, as shown in the drawing, when the tenth insulating film INS10 is not located between the first electrode AND and the reflective electrode layer RL but the eleventh insulating film INS11 is located therebetween, the thickness of the eleventh insulating film INS11 located in each of the first sub-pixel SP1, the second sub-pixel SP2, and the third sub-pixel SP3 may be different. For example, the thickness of the eleventh insulating film INS11 located in the first sub-pixel SP1 may be less than the thickness of the eleventh insulating film INS11 located in the second sub-pixel SP2, and the thickness of the eleventh insulating film INS11 located in the second sub-pixel SP2 may be less than the thickness of the eleventh insulating film INS11 located in the third sub-pixel SP3.

In one or more other embodiments, in the first sub-pixel SP1, neither the tenth insulating film INS10 nor the eleventh insulating film INS11 may be located between the first electrode AND and the reflective electrode layer RL, and in the second sub-pixel SP2, any one of the tenth insulating film INS10 or the eleventh insulating film INS11 may be located between the first electrode AND and the reflective electrode layer RL, and in the third sub-pixel SP3, both the tenth insulating film INS10 and the eleventh insulating film INS11 may be located between the first electrode AND and the reflective electrode layer RL.

In one or more other embodiments, a twelfth insulating film may be further located between the first electrode AND and the reflective electrode layer RL. In this case, in the first sub-pixel SP1, any one of the tenth insulating film INS10, the eleventh insulating film INS11, or the twelfth insulating film may be located between the first electrode AND and the reflective electrode layer RL, in the second sub-pixel SP2, any two of the tenth insulating film INS10, the eleventh insulating film INS11, and the twelfth insulating film may be located between the first electrode AND and the reflective electrode layer RL, and in the third sub-pixel SP3, all the tenth insulating film INS10, the eleventh insulating film INS11, and the twelfth insulating film may be located between the first electrode AND and the reflective electrode layer RL.

In summary, the distance between the first electrode AND and the reflective electrode layer RL may be different in the first sub-pixel SP1, the second sub-pixel SP2, and the third sub-pixel SP3. That is, to adjust the distance from the reflective electrode layer RL to the second electrode CAT according to the main wavelength of the light emitted from each of the first sub-pixel SP1, the second sub-pixel SP2, and the third sub-pixel SP3, the presence/absence or thickness of the tenth insulating film INS10 and the eleventh insulating film INS11 may be set in each of the first sub-pixel SP1, the second sub-pixel SP2, and the third sub-pixel SP3.

Although it is illustrated in the drawing that the total thickness of the insulating film located between the first electrode AND and the reflective electrode layer RL increases in the order of the first sub-pixel SP1, the second sub-pixel SP2, and the third sub-pixel SP3, the present disclosure is not limited thereto. That is, it is illustrated that the distance between the first electrode AND and the reflective electrode layer RL in the third sub-pixel SP3 is greater than the distance between the first electrode AND and the reflective electrode layer RL in the second sub-pixel SP2 and the distance between the first electrode AND and the reflective electrode layer RL in the first sub-pixel SP1, and that the distance between the first electrode AND and the reflective electrode layer RL in the second sub-pixel SP2 is greater than the distance between the first electrode AND and the reflective electrode layer RL in the first sub-pixel SP1, but the specification of the present disclosure is not limited thereto. The size relationship of the total thickness of the insulating film located between the first electrode AND and the reflective electrode layer RL in each of the first sub-pixel SP1, the second sub-pixel SP2, and the third sub-pixel SP3 may be variously changed depending on the resonance distance.

Each of the tenth vias VA10 may be connected to the reflective electrode layer RL exposed through the tenth insulating film INS10 and/or the eleventh insulating film INS11. The tenth vias VA10 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. The thickness of the tenth via VA10 in the second sub-pixel SP2 may be less than the thickness of the tenth via VA10 in the third sub-pixel SP3, and the thickness of the tenth via VA10 in the first sub-pixel SP1 may be less than the thickness of the tenth via VA10 in the second sub-pixel SP2, but the present disclosure is not limited thereto.

The first electrode AND of each of the light-emitting elements LE may be located on the eleventh interlayer insulating film INS11, and may be connected to the tenth via VA10. The first electrode AND of each of the light-emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light-emitting elements LE may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the first electrode AND of each of the light-emitting elements LE may be titanium nitride (TN).

The pixel-defining film PDL may be located on a part of the first electrode AND of each of the light-emitting elements LE. The pixel-defining film PDL may cover the edge of the first electrode AND of each of the light-emitting elements LE. The pixel-defining film PDL may serve to partition the first emission areas EA1, the second emission areas EA2, and the third emission areas EA3.

The first emission area EA1 may be defined as an area in which the first electrode AND, the light-emitting stack IL, and the second electrode CAT are sequentially stacked in the first sub-pixel SP1 to emit light. The second emission area EA2 may be defined as an area in which the first electrode AND, the light-emitting stack IL, and the second electrode CAT are sequentially stacked in the second sub-pixel SP2 to emit light. The third emission area EA3 may be defined as an area in which the first electrode AND, the light-emitting stack IL, and the second electrode CAT are sequentially stacked in the third sub-pixel SP3 to emit light.

The pixel-defining film PDL may include first to third pixel-defining films PDL1, PDL2, and PDL3. The first pixel-defining film PDL1 may be located on the edge of the first electrode AND of each of the light-emitting elements LE, the second pixel-defining film PDL2 may be located on the first pixel-defining film PDL1, and the third pixel-defining film PDL3 may be located on the second pixel-defining film PDL2. The first pixel-defining film PDL1, the second pixel-defining film PDL2, and the third pixel-defining film PDL3 may be formed of a silicon oxide (SiOx)-based inorganic layer, but the present specification is not limited thereto. The first pixel-defining film PDL1, the second pixel-defining film PDL2, and the third pixel-defining film PDL3 may each have a thickness of about 500 Å.

When the first pixel-defining film PDL1, the second pixel-defining film PDL2, and the third pixel-defining film PDL3 are formed as one pixel-defining film, the height of the one pixel-defining film increases, so that a first encapsulation inorganic film TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, to reduce or prevent the likelihood of the first encapsulation inorganic film TFE1 being cut off due to the step coverage, the first pixel-defining film PDL1, the second pixel-defining film PDL2, and the third pixel-defining film PDL3 may have a cross-sectional structure having a stepped portion. For example, the width of the first pixel-defining film PDL1 may be greater than the width of the second pixel-defining film PDL2 and the width of the third pixel-defining film PDL3, and the width of the second pixel-defining film PDL2 may be greater than the width of the third pixel-defining film PDL3. Each of the width of the first pixel-defining film PDL1, the width of the second pixel-defining film PDL2, and the width of the third pixel-defining film PDL3 refers to the length in the horizontal direction substantially perpendicular to the third direction DR3.

Each of the plurality of trenches TRC may penetrate the first pixel-defining film PDL1, the second pixel-defining film PDL2, and the third pixel-defining film PDL3. Furthermore, each of the plurality of trenches TRC may penetrate the eleventh insulating film INS11. The eleventh insulating film INS11 may be partially recessed at each of the plurality of trenches TRC.

At least one trench TRC may be located between adjacent sub-pixels SP1, SP2, and SP3. Although FIG. 7 illustrates that two trenches TRC are located between adjacent sub-pixels SP1, SP2, and SP3, the present specification is not limited thereto.

The light-emitting stack IL may include a plurality of intermediate layers. FIG. 7 illustrates that the light-emitting stack IL has a three-tandem structure including a first stack layer IL1, a second stack layer IL2, and a third stack layer IL3, but the present specification is not limited thereto. For example, the light-emitting stack IL may have a two-tandem structure including two intermediate layers.

In the three-tandem structure, the light-emitting stack IL may have a tandem structure including a plurality of stack layers IL1, IL2, and IL3 that emit different lights.

For example, the light-emitting stack IL may include the first stack layer IL1 that emits light of the first color, the second stack layer IL2 that emits light of the third color, and the third stack layer IL3 that emits light of the second color. The first stack layer IL1, the second stack layer IL2, and the third stack layer IL3 may be sequentially stacked.

The first stack layer IL1 may have a structure in which a first hole transport layer, a first organic light-emitting layer that emits light of the first color, and a first electron transport layer are sequentially stacked. The second stack layer IL2 may have a structure in which a second hole transport layer, a second organic light-emitting layer that emits light of the third color, and a second electron transport layer are sequentially stacked. The third stack layer IL3 may have a structure in which a third hole transport layer, a third organic light-emitting layer that emits light of the second color, and a third electron transport layer are sequentially stacked.

A first charge generation layer for supplying charges to the second stack layer IL2 and supplying electrons to the first stack layer IL1 may be located between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be located between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be located on the first electrodes AND and the pixel-defining film PDL, and may be located on the bottom surface of each trench TRC. Due to the trench TRC, the first stack layer IL1 may be cut off between adjacent sub-pixels SP1, SP2, and SP3. The second stack layer IL2 may be located on the first stack layer IL1. Due to the trench TRC, the second stack layer IL2 may be cut off between adjacent sub-pixels SP1, SP2, and SP3. A cavity ESS or an empty space may be located between the first stack layer IL1 and the second stack layer IL2. The third stack layer IL3 may be located on the second stack layer IL2. The third stack layer IL3 is not cut off by the trench TRC and may be located to cover the second stack layer IL2 in each of the trenches TRC. That is, in the three-tandem structure, each of the plurality of trenches TRC may be a structure for cutting off the first and second stack layers IL1 and IL2, the first charge generation layer, and the second charge generation layer of the display element layer EML between the sub-pixels SP1, SP2, and SP3 adjacent to each other. In addition, in the two-tandem structure, each of the trenches TRC may be a structure for cutting off the charge generation layer located between a lower intermediate layer and an upper intermediate layer, and the lower intermediate layer.

To stably cut off the first and second stack layers IL1 and IL2 of the display element layer EML between adjacent sub-pixels SP1, SP2, and SP3, the height of each of the plurality of trenches TRC may be greater than the height of the pixel-defining film PDL. The height of each of the plurality of trenches TRC refers to the length of each of the plurality of trenches TRC in the third direction DR3. The height of the pixel-defining film PDL refers to the length of the pixel-defining film PDL in the third direction DR3. To cut off the first to third stack layers IL1, IL2, and IL3 of the display element layer EML between the neighboring sub-pixels SP1, SP2, and SP3, another structure may exist instead of the trench TRC. For example, instead of the trench TRC, a reverse tapered partition wall may be located on the pixel-defining film PDL.

The number of the stack layers IL1, IL2, and IL3 that emit different lights is not limited to that shown in FIG. 7. For example, the light-emitting stack IL may include two intermediate layers. In this case, one of the two intermediate layers may be substantially the same as the first stack layer IL1, and the other may include a second hole transport layer, a second organic light-emitting layer, a third organic light-emitting layer, and a second electron transport layer. In this case, a charge generation layer for supplying electrons to one intermediate layer and supplying charges to the other intermediate layer may be located between the two intermediate layers.

In addition, FIG. 7 illustrates that the first to third stack layers IL1, IL2, and IL3 are all located in the first emission area EA1, the second emission area EA2, and the third emission area EA3, but the present specification is not limited thereto. For example, the first stack layer IL1 may be located in the first emission area EA1, and may be omitted from the second emission area EA2 and the third emission area EA3. Furthermore, the second stack layer IL2 may be located in the second emission area EA2, and may be omitted from the first emission area EA1 and the third emission area EA3. Further, the third stack layer IL3 may be located in the third emission area EA3 and may be omitted from the first emission area EA1 and the second emission area EA2. In this case, first to third color filters CF1, CF2, and CF3 of the optical layer OPL may be omitted.

The second electrode CAT may be located on the third stack layer IL3. The second electrode CAT may be located on the third stack layer IL3 in each of the plurality of trenches TRC. The second electrode CAT may be formed of a transparent conductive material (TCO), such as ITO or IZO that can transmit light or a semi-transmissive conductive material, such as magnesium (Mg), silver (Ag), or an alloy of Mg and Ag. When the second electrode CAT is formed of a semi-transmissive conductive material, the light emission efficiency may be improved in each of the first to third sub-pixels SP1, SP2, and SP3 due to a micro-cavity effect.

The encapsulation layer TFE may be located on the display element layer EML. The encapsulation layer TFE may include at least one inorganic film TFE1 and TFE2 to reduce or prevent permeation of oxygen or moisture into the display element layer EML. For example, the encapsulation layer TFE may include the first encapsulation inorganic film TFE1, and a second encapsulation inorganic film TFE2.

The first encapsulation inorganic film TFE1 may be located on the second electrode CAT. The first encapsulation inorganic film TFE1 may be formed as a multilayer in which one or more inorganic films selected from silicon nitride (SiNx), silicon oxy nitride (SiON), and silicon oxide (SiOx) are alternately stacked. The first encapsulation inorganic film TFE1 may be formed by a chemical vapor deposition (CVD) process.

The second encapsulation inorganic film TFE2 may be located on the first encapsulation inorganic film TFE1. The second encapsulation inorganic film TFE2 may be formed of titanium oxide (TiOx) or aluminum oxide (AlOx), but the present specification is not limited thereto. The second encapsulation inorganic film TFE2 may be formed by an atomic layer deposition (ALD) process. The thickness of the second encapsulation inorganic film TFE2 may be less than the thickness of the first encapsulation inorganic film TFE1.

The display panel 100 may further include an organic film APL. An organic film APL may be a layer for increasing the interfacial adhesion between the encapsulation layer TFE and the optical layer OPL. The organic film APL may be an organic film, such as acrylic resin, epoxy resin, phenolic resin, polyamide resin, or polyimide resin.

The optical layer OPL may include a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be located on the organic layer APL.

The first color filter CF1 may overlap the first emission area EA1 of the first sub-pixel SP1. The first color filter CF1 may transmit light of the first color (e.g., light of a red wavelength band). The red wavelength band may be approximately 600 nm to approximately 750 nm. Thus, the first color filter CF1 may transmit light of the first color among light emitted from the first emission area EA1.

The second color filter CF2 may overlap the second emission area EA2 of the second sub-pixel SP2. The second color filter CF2 may transmit light of the second color (e.g., light of a green wavelength band). The green wavelength band may be approximately 480 nm to approximately 560 nm. Thus, the second color filter CF2 may transmit light of the second color among light emitted from the second emission area EA2.

The third color filter CF3 may overlap the third emission area EA3 of the third sub-pixel SP3. The third color filter CF3 may transmit light of the third color (e.g., light of a blue wavelength band). The blue wavelength band may be approximately 370 nm to approximately 460 nm. Thus, the third color filter CF3 may transmit light of the third color among light emitted from the third emission area EA3.

The plurality of lenses LNS may be located on the first color filter CF1, the second color filter CF2, and the third color filter CF3, respectively. Each of the plurality of lenses LNS may be a structure for increasing a ratio of light directed to the front of the display device 10. Each of the plurality of lenses LNS may have a cross-sectional shape that is convex in an upward direction.

The filling layer FIL may be located on the plurality of lenses LNS. The filling layer FIL may have a refractive index (e.g., predetermined refractive index) such that light travels in the third direction DR3 at an interface between the filling layer FIL and the plurality of lenses LNS. Further, the filling layer FIL may be a planarization layer. The filling layer FIL may be an organic film, such as acrylic resin, epoxy resin, phenolic resin, polyamide resin, or polyimide resin.

The window module 120 may be located on the filling layer FIL. The window module 120 may be attached on the filling layer FIL. In this case, the filling layer FIL may serve to attach the window module 120. The window module 120 may protect the display module 110 from an external impact. The window module 120 may include an optical layer and adjust the path and polarization state of light emitted from the display module 110.

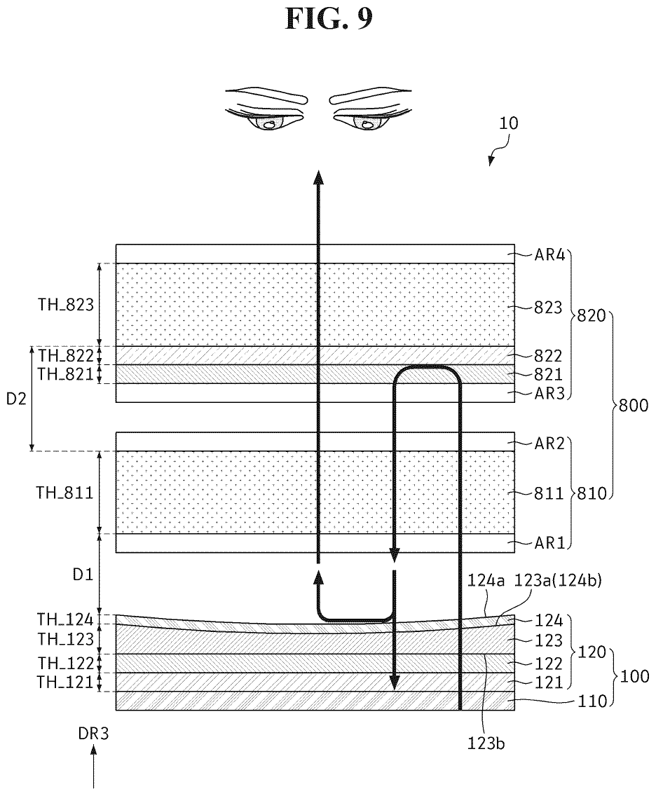

In some embodiments, the window module 120 may include a window 123 (see FIG. 9) including a glass substrate or a polymer resin, such as resin. In case in which the window 123 (see FIG. 9) is a glass substrate, it may serve as an encapsulation substrate. In case in which the window 123 (see FIG. 9) is a polymer resin, such as resin, it may be directly applied on the filling layer FIL. In some embodiments, an upper surface 120a of the window module 120 may be a curved surface concave toward the direction of the display module 110.

Hereinafter, the window module 120 and the optical module 800 will be described.

FIGS. 8 and 9 are cross-sectional views of a display device according to one or more embodiments.

Referring to FIGS. 8 and 9, the display panel 100 may include a display module 110 and a window module 120. The display module 110 has been described above, so the description thereof will be omitted. The optical module 800 may include a first optical module 810 and a second optical module 820. The first optical module 810 may be located on the display module 110 and the second optical module 820 may be located on the first optical module 810.

In some embodiments, the display module 110 and the first optical module 810 may be spaced apart from each other, and the first optical module 810 and the second optical module 820 may be spaced apart from each other. Air may be filled between the display module 110 and the first optical module 810 and between the first optical module 810 and the second optical module 820.

The window module 120 may include a first polarizing film 121, a first phase retardation film 122, the window 123, and a semi-transmissive reflective film 124. The first optical module 810 may include a first lens 811, a first coating film AR1, and a second coating film AR2. The second optical module 820 may include a second phase retardation film 821, a second polarizing film 822, a second lens 823, a third coating film AR3, and a fourth coating film AR4.

The first polarizing film 121 may be located on the display module 110. For example, the first polarizing film 121 may be located on the filling layer FIL of the display module 110. The first polarizing film 121 may have a first polarization axis extending in one direction. The first polarizing film 121 may be a linear polarizing film. The first polarizing film 121 may linearly polarize light in the direction of the first polarization axis. For example, the first polarizing film 121 may pass light vibrating in a direction parallel to the first polarization axis, and may block light vibrating in a direction other than parallel to the first polarization axis. In one or more embodiments, a thickness TH_121 of the first polarizing film 121 may be approximately 100 μm to approximately 300 μm.

In one or more embodiments, the first polarizing film 121 may be an absorption type polarizing film. In this case, the first polarizing film 121 may pass light vibrating in a direction parallel to the first polarization axis, and may absorb light vibrating in a direction not parallel to the first polarization axis.

The first phase retardation film 122 may be located on the first polarizing film 121. The first phase retardation film 122 may delay the phase of light passing through the first phase retardation film 122. When linearly polarized light passes through the first phase retardation film 122, it may be circularly polarized or elliptically polarized, and when circularly polarized or elliptically polarized light passes through the first phase retardation film 122, it may be linearly polarized. In one or more embodiments, the first phase retardation film 122 may be a quarter-wave plate (λ/4 plate). In one or more embodiments, a thickness TH_122 of the first phase retardation film 122 may be approximately 100 μm to approximately 300 μm.

The window 123 may be located on the first phase retardation film 122. The window 123 may protect the display module 110 from external impact. As described above, the window 123 may include a glass substrate or a polymer resin, such as resin. The window 123 may include a first surface 123a located on the side of the light-emitting surface toward the user, and a second surface 123b located on the side of the display module 110, which is the opposite side of the first surface 123a. The semi-transmissive reflective film 124 may be located on the first surface 123a of the window 123, and the first phase retardation film 122 and the first polarizing film 121 may be located on the second surface 123b of the window 123.

In some embodiments, the first surface 123a of the window 123 may be a curved surface that is concave toward the display module 110. The radius of curvature of the first surface 123a may be approximately 100 mm or more, but is not limited thereto. As the first surface 123a of the window 123 is a curved surface, the upper and lower surfaces of the semi-transmissive reflective film 124 located on the first surface 123a of the window 123 may be curved.

In one or more embodiments, a thickness TH_123 of the window 123 may be approximately 2 mm. The thickness TH_123 of the window 123 may mean a thickness from one point of the second surface 123b in a direction substantially perpendicular to the second surface 123b, and may mean the average thickness in the entire portion.

The semi-transmissive reflective film 124 may be located on the window 123. The semi-transmissive reflective film 124 may transmit part of the light, and may reflect the remaining part of the light. Light transmitted through the semi-transmissive reflective film 124 may be transmitted without phase change. Light reflected from the semi-transmissive reflective film 124 may be reflected with its phase reversed. For example, left-hand circularly polarized light may be reflected from the semi-transmissive reflective film 124 to become right-hand circularly polarized light, and right-hand circularly polarized light may be reflected from the semi-transmissive reflective film 124 to become left-hand circularly polarized light.

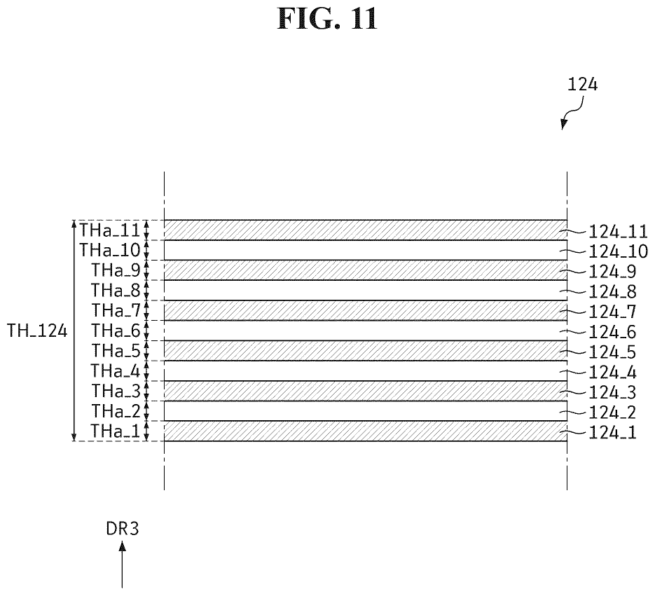

In some embodiments, the semi-transmissive reflective film 124 may be formed by a deposition process. For example, the semi-transmissive reflective film 124 may be a film formed by depositing at least one of silicon oxide (SiOx) and titanium oxide (TiOx) on the window 123. In some embodiments, the semi-transmissive reflective film 124 may have a multilayer structure in which a plurality of layers are stacked. The detailed structure of the semi-transmissive reflective film 124 will be described later with reference to FIG. 11.

The semi-transmissive reflective film 124 may include a first surface 124a located on the side of the light-emitting surface toward the user, and a second surface 124b located on the side of the display module 110, which is the opposite side of the first surface 124a. In some embodiments, the first surface 124a and the second surface 124b of the semi-transmissive reflective film 124 may be curved surfaces that are concave toward the display module 110. The semi-transmissive reflective film 124 may be formed conformally according to the shape of the first surface 123a of the window 123. As the first surface 123a of the semi-transmissive reflective film 124 is curved, the viewing angle and magnification may be increased. Accordingly, the number of components of the optical module 800 may be reduced and the thickness of the display device 10 may be reduced.

The first lens 811 may be located on the semi-transmissive reflective film 124. The first lens 811 may be arranged to be spaced apart from the semi-transmissive reflective film 124. The first lens 811 may magnify an image formed by light generated from the display module 110. Lenses of various shapes, such as a convex lens, meniscus lens, and Fresnel lens, may be used as the first lens 811, and the shape of the first lens 811 is not limited. In one or more embodiments, a thickness TH_811 of the first lens 811 may be approximately 5 mm to approximately 20 mm. For example, the thickness TH_811 of the first lens 811 may be approximately 7 mm to approximately 15 mm.

The first coating film AR1 may be located on one surface of the first lens 811. For example, the first coating film AR1 may be located on the lower surface of the first lens 811. The first coating film AR1 may be located between the first lens 811 and the window module 120. The first coating film AR1 may be an anti-reflection layer. The first coating film AR1 may be formed by an anti-reflection coating. The first coating film AR1 may reduce or prevent the reflection of light incident on the incident surface of the first optical module 810 (e.g., the lower surface of the first lens 811). Accordingly, the light output rate may be improved and the occurrence of stray light can be reduced or minimized.

The second coating film AR2 may be located on the other surface of the first lens 811. For example, the second coating film AR2 may be located on the upper surface of the first lens 811. The second coating film AR2 may be located between the first lens 811 and the second optical module 820. The second coating film AR2 may be an anti-reflection layer. The second coating film AR2 may be formed by an anti-reflection coating. The second coating film AR2 may reduce or prevent reflection of light incident on the incident surface of the first optical module 810 (e.g., the upper surface of the first lens 811). Accordingly, the light output rate may be improved and the occurrence of stray light can be reduced or minimized.

The second phase retardation film 821 may be located on the first lens 811. The second phase retardation film 821 may delay the phase of light passing through the second phase retardation film 821. When linearly polarized light passes through the second phase retardation film 821, it may be circularly polarized or elliptically polarized, and when circularly polarized or elliptically polarized light passes through the second phase retardation film 821, it may be linearly polarized. In one or more embodiments, the second phase retardation film 821 may be a quarter-wave plate (λ/4 plate). In one or more embodiments, a thickness TH_821 of the second phase retardation film 821 may be approximately 100 μm to approximately 300 μm.

The second polarizing film 822 may be located on the second phase retardation film 821. The second polarizing film 822 may have a second polarization axis extending in one direction. The second polarizing film 822 may be a linear polarizing film. The second polarizing film 822 may linearly polarize light in the direction of the second polarization axis. For example, the second polarizing film 822 may pass light vibrating in a direction parallel to the second polarization axis, and may block light vibrating in a direction other than parallel to the second polarization axis. In one or more embodiments, a thickness TH_822 of the second polarizing film 822 may be approximately 100 μm to approximately 300 μm.

In one or more embodiments, the second polarizing film 822 may be a reflective polarizing film. In this case, the second polarizing film 822 may pass light vibrating in a direction parallel to the second polarization axis and reflect light vibrating in a direction not parallel to the first polarization axis.

The second lens 823 may magnify an image formed by light generated from the display module 110. Lenses of various shapes, such as a convex lens, meniscus lens, and Fresnel lens, may be used as the second lens 823, and the shape of the second lens 823 is not limited. The second lens 823 may include the same lens or different type of lens as the first lens 811. In one or more embodiments, a thickness TH_823 of the second lens 823 may be approximately 1 mm to approximately 15 mm. For example, the thickness TH_823 of the second lens 823 may be approximately 3 mm to approximately 10 mm.

The third coating film AR3 may be located on one surface of the second lens 823. For example, the third coating film AR3 may be located on the lower surface of the second lens 823. The third coating film AR3 may be located between the first optical module 810 and the second lens 823. The third coating film AR3 may be an anti-reflection layer. The third coating film AR3 may be formed by an anti-reflection coating. The third coating film AR3 may reduce or prevent reflection of light incident on the incident surface of the second optical module 820 (e.g., the lower surface of the second phase retardation film 821). Accordingly, the light output rate may be improved and the occurrence of stray light can be reduced or minimized.

The fourth coating film AR4 may be located on the other surface of the second lens 823. For example, the fourth coating film AR4 may be located on the upper surface of the second lens 823. The fourth coating film AR4 may be an anti-reflection layer. The fourth coating film AR4 may be formed by an anti-reflection coating. The fourth coating film AR4 may reduce or prevent reflection of light incident on the light-emitting surface of the display device 10 (e.g., the upper surface of the second lens 823) from the outside. Accordingly, external reflection may be reduced or minimized, and visibility may be improved.

In some embodiments, at least one of the first to fourth coating films AR1, AR2, AR3, or AR4 may be omitted depending on the degree of improvement in transmittance and reflectance of each member.

The first polarization axis of the first polarizing film 121 and the second polarization axis of the second polarizing film 822 may be substantially perpendicular to each other. For example, when the first polarization axis extends in the third direction DR3, which is the perpendicular direction, the second polarization axis may extend in the horizontal direction, which is substantially perpendicular to the third direction DR3.

The first phase retardation film 122 may have a first optical axis. The first optical axis of the first phase retardation film 122 may be offset from the first polarization axis of the first polarizing film 121 and/or the second polarization axis of the second polarizing film 822 by an angle within a range of more than 0 degrees and less than about 90 degrees. In one or more embodiments, the first optical axis may be offset from approximately 45 degrees relative to the first polarization axis and/or the second polarization axis, but the present disclosure is not limited thereto.

The second phase retardation film 821 may have a second optical axis. The second optical axis of the second phase retardation film 821 may be offset from the first polarization axis of the first polarizing film 121 and/or the second polarization axis of the second polarizing film 822 by an angle within a range of more than 0 degrees and less than about 90 degrees. In one or more embodiments, the second optical axis may be offset from approximately 45 degrees relative to the first polarization axis and/or the second polarization axis, but the present disclosure is not limited thereto.

The direction in which the first optical axis of the first phase retardation film 122 is offset with respect to the first polarization axis and/or the second polarization axis may be opposite to the direction in which the second optical axis of the second phase retardation film 821 is offset with respect to the first polarization axis and/or the second polarization axis. For example, the first phase retardation film 122 may be offset by about −45 degrees with respect to the first polarization axis and/or the second polarization axis, and the second phase retardation film 821 may be offset by about +45 degrees with respect to the first polarization axis and/or the second polarization axis. Alternatively, the first phase retardation film 122 may be offset by +45 with respect to the first polarization axis and/or the second polarization axis, and the second phase retardation film 821 may be offset by about −45 degrees with respect to the first polarization axis and/or the second polarization axis.

The phase retardation direction of light passing through the first phase retardation film 122 may be different from the phase retardation direction of light passing through the second phase retardation film 821. For example, light passing through the first phase retardation film 122 may be delayed by −λ/4, and light passing through the second phase retardation film 821 may be delayed by +λ/4.

As described above, the display module 110 and the first optical module 810 may be spaced apart from each other, and the first optical module 810 and the second optical module 820 may be spaced apart from each other. For example, a distance D1 between the first lens 811 and the semi-transmissive reflective film 124 may be approximately 0.5 mm or more, and a distance D2 between the first lens 811 and the second lens 823 may be approximately 0.3 mm or more. The distance D1 between the first lens 811 and the semi-transmissive reflective film 124 means the shortest distance between the first lens 811 and the semi-transmissive reflective film 124, and the distance D2 between the first lens 811 and the second lens 823 means the shortest distance between the first lens 811 and the second lens 823.

The display device 10 includes the window module 120 and the optical module 800, thereby implementing folded optics that folds an optical path. Accordingly, the total track length, which is the total length of the optical path, may be increased, and the thickness of the display device 10 may be reduced or minimized.

In addition, as optical elements, such as the first polarizing film 121, the first phase retardation film 122, and the semi-transmissive reflective film 124, which are part of a folded optics configuration, are mounted on the window module 120 together with the window 123, the number of the components located in the optical module 800 may be reduced or minimized.

For example, in a case where a separate optical element having the same function as the semi-transmissive reflective film 124 is placed between the first optical module 810 and the window 123, an additional space where a thickness of the separate optical element itself and the separate optical element are to be located may be required.

On the other hand, in the display device 10, the thickness of the optical module 800 and the thickness of the display device 10 may be reduced or minimized by directly mounting the semi-transmissive reflective film 124 on the upper surface of the window 123. In addition, the light output rate may be improved by reducing the number of optical elements.

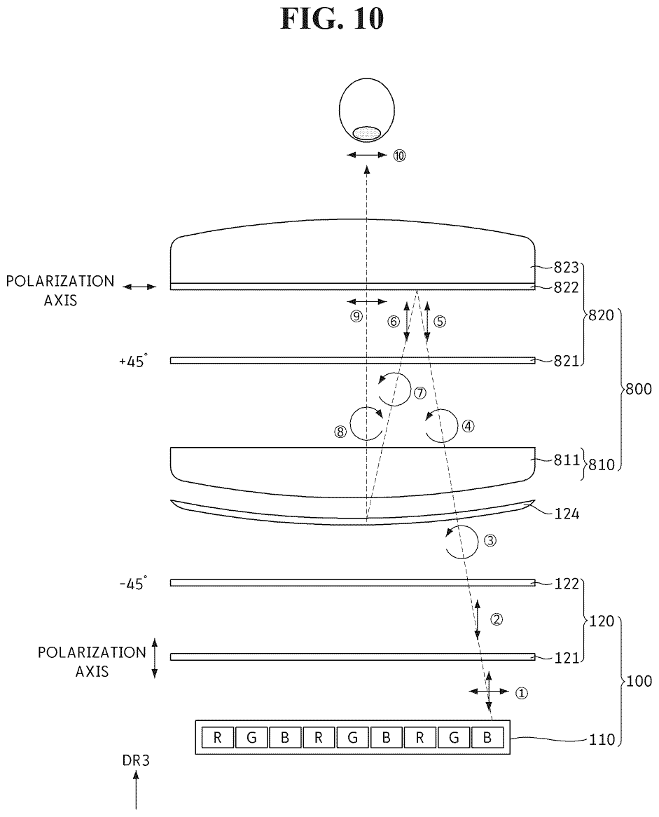

Hereinafter, the path and polarization state of light moving through the folded optics of the display device 10 will be described with reference to FIG. 10.

FIG. 10 is a schematic diagram for explaining a path of light and a polarization state of light emitted from a display device according to one or more embodiments.

Referring to FIG. 10, it is shown that the first polarization axis of the first polarizing film 121 extends in the perpendicular direction, and the second polarization axis of the second polarizing film 822 extends in the horizontal direction. In addition, it is shown that the first polarizing film 121 is an absorption type polarizing film, and the second polarizing film 822 is a reflective polarizing film. Also, it is shown that the first optical axis of the first phase retardation film 122 is offset by about −45 degrees with respect to the vertical direction, and the second optical axis of the second phase retardation film 821 is offset by about +45 degrees with respect to the vertical direction.

The light emitted from the display module 110 may be unpolarized light \textcircled{1}.

The unpolarized light \textcircled{1} may pass through the first polarizing film 121 having a first polarization axis in the perpendicular direction, and may be converted into vertically polarized light \textcircled{2} that vibrates in the perpendicular direction.

The vertically polarized light \textcircled{2} that passed through the first polarizing film 121 may pass through the first phase retardation film 122, which has a first optical axis offset by about −45 degrees with respect to the perpendicular direction, and may be converted into left-hand circularly polarized light \textcircled{3}.

Some of the left-hand circularly polarized light \textcircled{3} that passed through the first phase retardation film 122 may pass through the semi-transmissive reflective film 124. The left-hand circularly polarized light \textcircled{3} that passed through the semi-transmissive reflective film 124 may have the same polarization state as the left-hand circularly polarized light \textcircled{3} that passed through the first phase retardation film 122 without a change in the polarization state. Although not illustrated in FIG. 10, the other part of the left-hand circularly polarized light \textcircled{3} that passed through the first phase retardation film 122 may be reflected on the semi-transmissive reflective film 124.

The left-hand circularly polarized light \textcircled{3} that passed through the semi-transmissive reflective film 124 may be magnified as it passes through the first lens 811. Left-hand circularly polarized light \textcircled{4} that passed through the first lens 811 may have the same polarization state as the left-hand circularly polarized light \textcircled{3} that passed through the semi-transmissive reflective film 124 without a change in the polarization state.

The left-hand circularly polarized light \textcircled{4} that passed through the first lens 811 may pass through the second phase retardation film 821 having a second polarization axis that is offset by about +45 degrees with respect to the vertical direction, and may be converted again into a vertically polarized light \textcircled{5}.

Because the vertically polarized light \textcircled{5} that passed through the second phase retardation film 821 is light polarized in a different direction from the second polarization axis in the perpendicular direction, it may be reflected from the second polarizing film 822. A vertically polarized light \textcircled{6} reflected from the second polarizing film 822 may have the same polarization state as the vertically polarized light \textcircled{5} that passed through the second phase retardation film 821 without a change in the polarization state.

The vertically polarized light \textcircled{6} reflected from the second polarizing film 822 may pass through the second phase retardation film 821, which has a second optical axis offset by about +45 degrees with respect to the perpendicular direction, and may be converted into a left-hand circularly polarized light \textcircled{7}. When passing through the first phase retardation film 122, the vertically polarized light \textcircled{2} that passed through the first polarizing film 121 passes through the first phase retardation film 122 having the first optical axis offset by about −45 degrees with respect to the perpendicular direction in the third direction DR3, thereby converting into the left-hand circularly polarized light \textcircled{3}. However, when passing through the first phase retardation film 122, the vertically polarized light \textcircled{6} reflected from the second polarizing film 822 passes through the second phase retardation film 821 having the second optical axis offset by about +45 degrees with respect to the perpendicular direction in the opposite direction of the third direction DR3, thereby converting into the left-hand circularly polarized light \textcircled{7}.

The left-hand circularly polarized light \textcircled{7} that passed through the second phase retardation film 821 may pass through the first lens 811 and the image may be magnified. The left-hand circularly polarized light \textcircled{7} that passed through the first lens 811 may have the same polarization state as the left-hand circularly polarized light \textcircled{7} that passed through the second phase retardation film 821 without a change in the polarization state.

Some of the left-hand circularly polarized light \textcircled{7} that passed through the first lens 811 may be reflected from the semi-transmissive reflective film 124, and may be converted into a right-hand circularly polarized light \textcircled{8} by the left and right reverse effect.

The right-hand circularly polarized light \textcircled{8} reflected from the semi-

transmissive reflective film 124 may pass through the first lens 811, and the image may be magnified. The right-hand circularly polarized light \textcircled{8} that passed through the first lens 811 may have the same polarization state as the right-hand circularly polarized light \textcircled{8} reflected from the semi-transmissive reflective film 124 without a change in the polarization state.

Some of the right-hand circularly polarized light \textcircled{8} that passed through the first lens 811 may pass through the second phase retardation film 821 having a second optical axis that is offset by about +45 degrees with respect to the vertical direction, and may be converted into a horizontally polarized light \textcircled{9}.

Because the horizontally polarized light \textcircled{9} that passed through the second phase retardation film 821 is light polarized in the same direction as the second polarization axis in the horizontal direction, it may pass through the second polarizing film 822. The horizontally polarized light \textcircled{9} that passed through the second polarizing film 822 may have the same polarization state as the horizontally polarized light \textcircled{9} that passed through the second phase retardation film 821 without a change in the polarization state.

The horizontally polarized light \textcircled{9} that passed through the second polarizing film 822 may pass through the second lens 823 and the image may be magnified. Horizontally polarized light (10 that passed through the second lens 823 may have the same polarization state as the horizontally polarized light \textcircled{9} that passed through second polarizing film 822 without a change in the polarization state. The horizontally polarized light \textcircled{10} that passed through the second lens 823 may be provided to the user.

The display device 10 includes folded optics so that light passes through two lenses four times, thereby increasing the frequency of image magnification and increasing the degree to which the image is magnified by increasing the optical path. Accordingly, the thickness of the display device 10 is reduced, but an image that is further magnified can be obtained.

FIG. 11 is a cross-sectional view illustrating a stacked structure of a semi-transparent reflective film according to one or more embodiments.

Referring to FIG. 11, the semi-transmissive reflective film 124 may have a multilayered structure in which a plurality of layers are stacked. The semi-transmissive reflective film 124 may have a structure in which first material layers and second material layers are alternately stacked. The first material layer may include silicon oxide, and the second material layer may include titanium oxide. For example, the first material layer may include SixOy (x, y are natural numbers), and the second material layer may include TixOy (x, y are natural numbers). The semi-transmissive reflective film 124 may be formed through a deposition process, but is not limited thereto.

The first material layer may have a lower refractive index than the second material layer. For example, the refractive index of the first material layer may be approximately 1.91 to approximately 1.93, and the refractive index of the second material layer may be approximately 3.45 to approximately 3.47. In the present specification, the refractive index of the first material layer and the refractive index of the second material layer refer to values measured through light with a peak wavelength of about 550 nm at 20° C. and 1 atm.

For example, the semi-transmissive reflective film 124 may include first to eleventh layers 124_1 to 124_11. The first layer 124_1, the third layer 124_3, the fifth layer 124_5, the seventh layer 124_7, the ninth layer 124_9, and the eleventh layer 124_11 will be composed of the first material layer. The second layer 124_2, the fourth layer 124_4, the sixth layer 124_6, the eighth layer 124_8, and the tenth layer 124_10 may be composed of the second material layer.

A thickness THa_1 of the first layer 124_1 may be approximately 58 nm to approximately 65 nm. A thickness THa_2 of the second layer 124_2 may be approximately 69 nm to approximately 77 nm. A thickness THa_3 of the third layer 124_3 may be approximately 92 nm to approximately 103 nm. A thickness THa_4 of the fourth layer 124_4 may be approximately 69 nm to approximately 77 nm. A thickness THa_5 of the fifth layer 124_5 may be approximately 99 nm to approximately 111 nm. A thickness THa_6 of the sixth layer 124_6 may be approximately 37 nm to approximately 42 nm. A thickness THa_7 of the seventh layer 124_7 may be approximately 43 nm to approximately 49 nm. A thickness THa_8 of the eighth layer 124_8 may be approximately 48 nm to approximately 54 nm. A thickness THa_9 of the ninth layer 124_9 may be approximately 69 nm to approximately 77 nm. A thickness THa_10 of the tenth layer 124_10 may be approximately 8 nm to approximately 10 nm. A thickness THa_11 of the eleventh layer 124_11 may be approximately 113 nm to approximately 126 nm. The total thickness TH_124 of the semi-transmissive reflective film 124 may be approximately 705 nm to approximately 791 nm.

In the drawing, the semi-transmissive reflective film 124 is shown as having a structure in which a total of eleven layers are stacked, including six first material layers and five second material layers, but the present disclosure is not limited thereto. The number of stacked semi-transmissive reflective films 124 may vary. For example, the number of stacked semi-transmissive reflective films 124 may be nine or more. For example, the number of stacked first material layers may be five or more, and the number of stacked second material layers may be four or more.

In the display device 10, by directly mounting the semi-transmissive reflective film 124 on the window 123, the number of the components located in the optical module 800 may be reduced or minimized. Accordingly, the thickness of the display device 10 may be reduced or minimized and the light output rate may be improved.

Hereinafter, other embodiments of the display device according to one or more embodiments will be described. In the following embodiments, description of the same components as those of the above-described embodiments, which are denoted by like reference numerals, will be omitted or simplified, and differences will be mainly described.

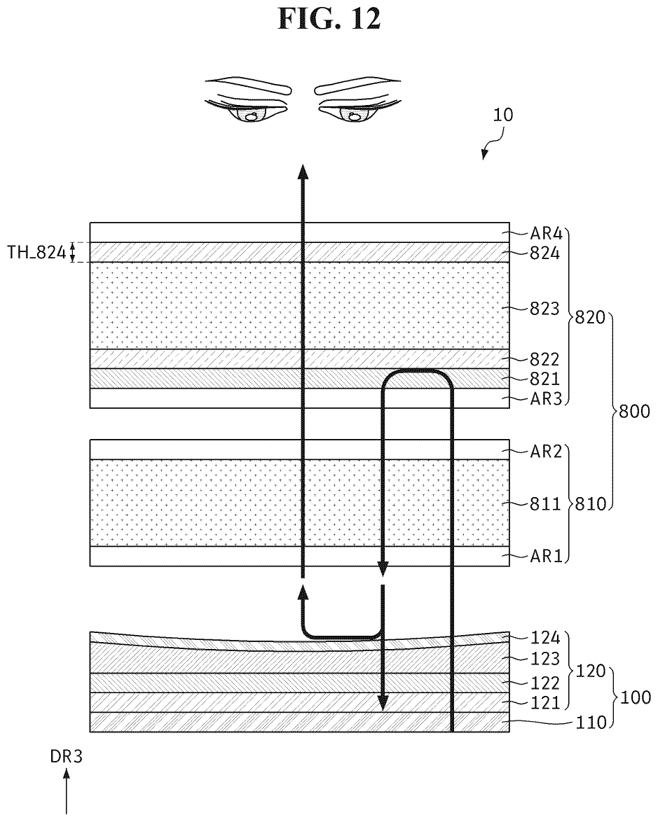

FIG. 12 is a cross-sectional view illustrating a display device according to one or more other embodiments.

Referring to FIG. 12, the display device 10 described with reference to FIG. 12 is different from the display device 10 according to one or more embodiments described with reference to FIG. 9 and the like in further including a third polarizing film 824.

For example, the display device 10 may further include the third polarizing film 824. The third polarizing film 824 may be located on the second lens 823. For example, the third polarizing film 824 may be located between the second lens 823 and the fourth coating film AR4. The third polarizing film 824 may have a third polarization axis extending on one direction. The third polarizing film 824 may be a linear polarizing film. The third polarizing film 824 may linearly polarize light in the direction of the third polarization axis. For example, the third polarizing film 824 may pass light vibrating in a direction parallel to the third polarization axis, and may block light vibrating in a direction other than parallel to the third polarization axis. In one or more embodiments, a thickness TH_824 of the third polarizing film 824 may be approximately 100 μm to approximately 300 μm.

In one or more embodiments, the third polarizing film 824 may be an absorption type polarizing film. In this case, the third polarizing film 824 may pass light vibrating in a direction parallel to the second polarization axis and absorb light vibrating in a direction not parallel to the first polarization axis.

The third polarization axis of the third polarizing film 824 may extend in a direction parallel to the second polarization axis of the second polarizing film 822. The third polarization axis of the third polarizing film 824 may be substantially perpendicular to the first polarization axis of the first polarizing film 121. For example, in case where the second polarization axis is extended in the third direction DR3, the third polarization axis may be extended in the third direction DR3.

The display device 10 may reduce external reflection by including the third polarizing film 824. In addition, visibility may be improved because the third polarizing film 824 blocks stray light that does not vibrate in the same direction as the second polarization axis of the second polarizing film 822.

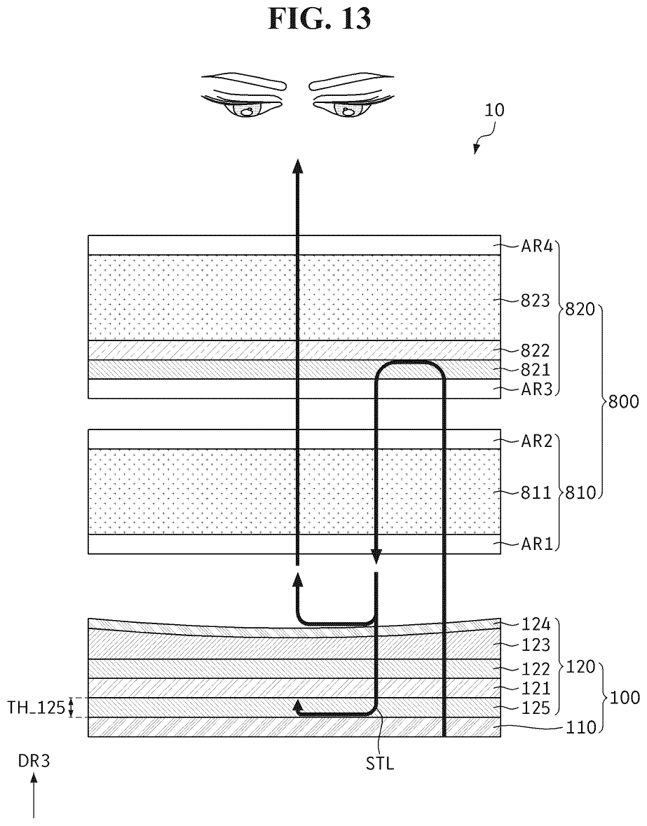

FIG. 13 is a cross-sectional view illustrating a display device according to still one or more other embodiments.

Referring to FIG. 13 in conjunction with FIG. 10, the presently described display device 10 is different from the display device 10 of the embodiments described above with reference to FIGS. 9 to 12 in further including a third phase retardation film 125.

For example, the display device 10 may further include the third phase retardation film 125. The third phase retardation film 125 may be located on the display module 110. For example, the third phase retardation film 125 may be located between the display module 110 and the first polarizing film 121. The third phase retardation film 125 may delay the phase of light that passed through the third phase retardation film 125. When linearly polarized light passes through the third phase retardation film 125, it may be circularly polarized or elliptically polarized, and when circularly polarized or elliptically polarized light passes through the third phase retardation film 125, it may be linearly polarized. In one or more embodiments, the third phase retardation film 125 may be a quarter-wave plate (λ/4 plate). In one or more embodiments, a thickness TH_125 of the third phase retardation film 125 may be approximately 100 μm to approximately 300 μm.

The third phase retardation film 125 may have a third optical axis. The third optical axis of the third phase retardation film 125 may be offset from the first polarization axis of the first polarizing film 121 and/or the second polarization axis of the second polarizing film 822 by an angle within a range of more than 0 degrees and less than about 90 degrees. In one or more embodiments, the third optical axis may be offset by approximately 45 degrees relative to the first polarization axis and/or the second polarization axis, but the present disclosure is not limited thereto.

The direction in which the first optical axis of the third phase retardation film 125 is offset with respect to the first polarization axis and/or the second polarization axis may be the same as the direction in which any one of the first optical axis of the first phase retardation film 122 or the second optical axis of the second phase retardation film 821 are offset with respect to the first polarization axis and/or the second polarization axis. As an example, the third phase retardation film 125 may be offset in a direction of about −45 degrees with respect to the first polarization axis and/or the second polarization axis. As another example, the third phase retardation film 125 may be offset in a direction of about +45 degrees with respect to the first polarization axis and/or the second polarization axis.

The phase retardation direction of light passing through the third phase retardation film 125 may be the same as any one of the phase retardation direction of light passing through the first phase retardation film 122 or the phase retardation direction of light passing through the second phase retardation film 821. As an example, light passing through the third phase retardation film 125 may be delayed by −λ/4. As another example, light passing through the third phase retardation film 125 may be delayed by +λ/4.

As the display device 10 includes the third phase retardation film 125, visibility may be improved by suppressing reflection of stray light.

For example, some of the light emitted from the display module 110 may be reflected by the semi-transmissive reflective film 124, or may pass through the semi-transmissive reflective film 124 and move toward the display module 110. Such stray light STL may be linearly polarized in one direction while passing through the first polarizing film 121, the linearly polarized stray light STL may be circularly polarized by passing through the third phase retardation film 125, and the circularly polarized stray light STL may be reflected by the display module 110, pass through the third phase retardation film 125 again, and may be linearly polarized in a direction substantially perpendicular to the one direction. Accordingly, the linearly polarized stray light STL in a direction substantially perpendicular to the first polarization axis of the first polarizing film 121 may be blocked by the first polarizing film 121, and may not be emitted to the outside. Accordingly, the visibility of the display device 10 may be improved.

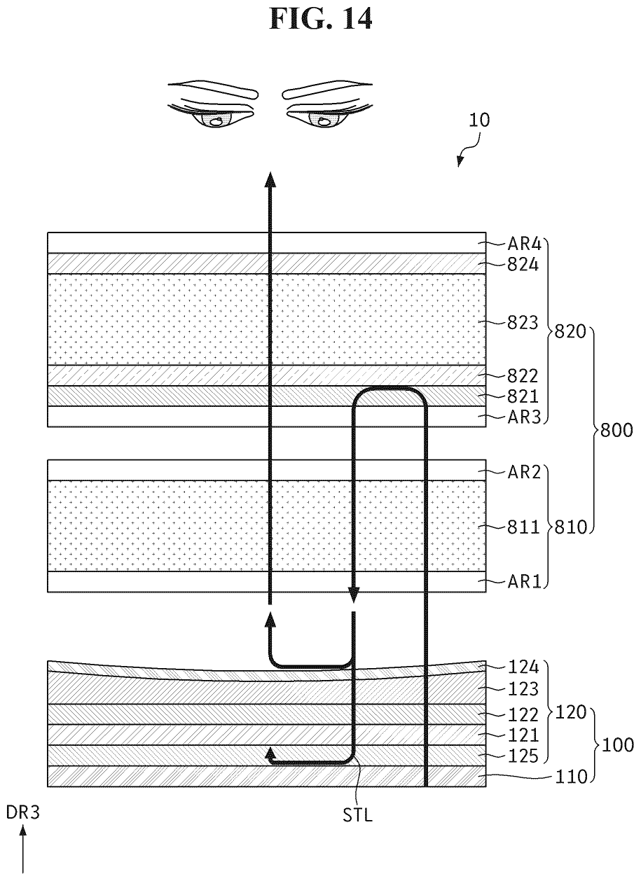

FIG. 14 is a cross-sectional view illustrating a display device according to still one or more other embodiments.

Referring to FIG. 14, the presently described display device 10 is different from the display device 10 of the embodiments described above with reference to FIGS. 9, 12, and 13 in further including a third polarizing film 824 and a third phase retardation film 125.

For example, the display device 10 may include both the third polarizing film 824 and the third phase retardation film 125. Accordingly, as described above, in the display device 10, external reflection may be reduced and visibility may be improved by including the third polarizing film 824, and visibility may be improved by including the third phase retardation film 125.

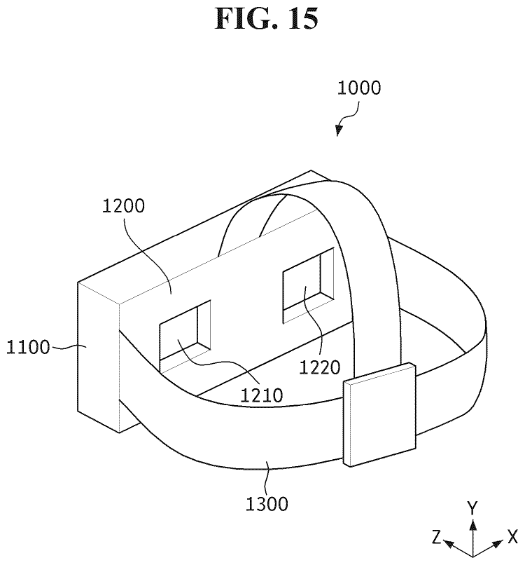

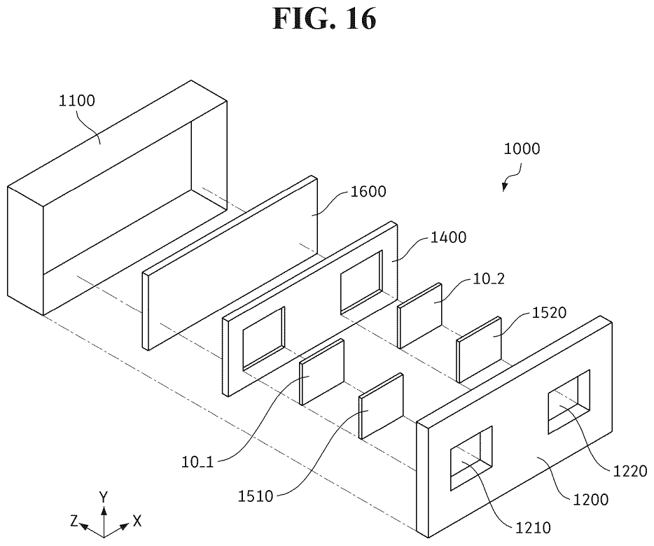

FIG. 15 is a perspective view illustrating a head-mounted display device according to one or more embodiments. FIG. 16 is an exploded perspective view illustrating an example of the head-mounted display device of FIG. 15.

Referring to FIGS. 15 and 16, a head-mounted display device 1000 according to one or more embodiments includes a first display device 10_1, a second display device 10_2, a display device housing 1100, a housing cover 1200, a first eyepiece 1210, a second eyepiece 1220, a head-mounted band 1300, a middle frame 1400, a first optical member 1510, a second optical member 1520, and a control circuit board 1600.

The first display device 10_1 may provide an image to the user's left eye, and the second display device 10_2 may provide an image to the user's right eye. Because each of the first display device 10_1 and the second display device 10_2 is substantially the same as the display device 10 described in conjunction with FIGS. 1 to 14, the description of the first display device 10_1 and the second display device 10_2 will be omitted.

The first optical member 1510 may be located between the first display device 10_1 and the first eyepiece 1210. The second optical member 1520 may be located between the second display device 10_2 and the second eyepiece 1220. Each of the first optical member 1510 and the second optical member 1520 may include at least one convex lens.

The middle frame 1400 may be located between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be located between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and may transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

The display device housing 1100 may accommodate the first display device 10_1, the second display device 10_2, the middle frame 1400, the first optical member 1510, the second optical member 1520, and the control circuit board 1600. The housing cover 1200 may be located to cover one open surface of the display device housing 1100. The housing cover 1200 may include the first eyepiece 1210 at which the user's left eye is located and the second eyepiece 1220 at which the user's right eye is located. FIGS. 15 and 16 illustrate that the first eyepiece 1210 and the second eyepiece 1220 are located separately, but the present specification is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Accordingly, the user may view the image of the first display device 10_1 magnified as a virtual image by the first optical member 1510 through the first eyepiece 1210, and may view the image of the second display device 10_2 magnified as a virtual image by the second optical member 1520 through the second eyepiece 1220.

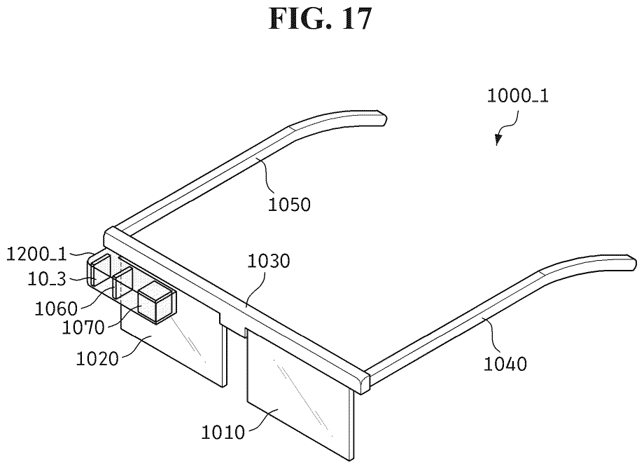

The head-mounted band 1300 may secure the display device housing 1100 to the user's head such that the first eyepiece 1210 and the second eyepiece 1220 of the housing cover 1200 remain located on the user's left and right eyes, respectively. When the display device housing 1200 is implemented to be lightweight and compact, the head-mounted display device 1000 may be provided with, as shown in FIG. 17, an eyeglass frame instead of a head-mounted band 1300.

In addition, the head-mounted display device 1000 may further include a battery for supplying power, an external memory slot for accommodating an external memory, and an external connection port and wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi® module, or a Bluetooth® module (Wi-Fi® being a registered trademark of the non-profit Wi-Fi Alliance, and Bluetooth® being a registered trademark of Bluetooth Sig, Inc., Kirkland, WA).

FIG. 17 is a perspective view illustrating a head-mounted display device according to one or more other embodiments.

Referring to FIG. 17, a head-mounted display device 1000_1 according to one or more other embodiments may be an eyeglasses-type display device in which a display device housing 1200_1 is implemented in a lightweight and compact manner. The head-mounted display device 1000_1 according to one or more other embodiments may include a display device 10_3, a left eye lens 1010, a right eye lens 1020, a support frame 1030, temples 1040 and 1050, an optical member 1060, an optical path conversion member 1070, and the display device housing 1200_1.

The display device housing 1200_1 may include the display device 10_3, the optical member 1060, and the optical path conversion member 1070. An image displayed on the display device 10_3 may be magnified by the optical member 1060, and the optical path may be converted by the optical path conversion member 1070 to provide the image to the user's right eye through the right eye lens 1020. As a result, the user may view an augmented reality image, through the right eye, in which a virtual image displayed on the display device 10_3 and a real image seen through the right eye lens 1020 are combined.

FIG. 17 illustrates that the display device housing 1200_1 is located at the end on the right side of the support frame 1030, but the present specification is not limited thereto. For example, the display device housing 1200_1 may be located on the left end of the support frame 1030, and in this case, the image of the display device 10_3 may be provided to the user's left eye. Alternatively, the display device housing 1200_1 may be located on both the left and right ends of the support frame 1030, and in this case, the user may view the image displayed on the display device 10_3 through both the left and right eyes.

In concluding the detailed description, those skilled in the art will appreciate that many variations and modifications can be made to the embodiments without substantially departing from the aspects of the present disclosure. Therefore, the disclosed embodiments are used in a generic and descriptive sense only and not for purposes of limitation.

What is claimed is:

1. A display device comprising:
a display panel comprising a display module, and a window module above the display module and comprising:
a first polarizing film above the display module;
a first phase retardation film above the first polarizing film;
a window above the first phase retardation film; and
a semi-transmissive reflective film above the window; and
an optical module above the display panel, and comprising:
a first optical module comprising a first lens above the semi-transmissive reflective film; and
a second optical module comprising a second phase retardation film above the first lens, a second polarizing film above the second phase retardation film, and a second lens above the second polarizing film.

2. The display device of claim 1, wherein the semi-transmissive reflective film comprises a curved surface.

3. The display device of claim 2, wherein the window comprises a curved first surface adjacent to the semi-transmissive reflective film.

4. The display device of claim 3, wherein a radius of curvature of the first surface is about 100 mm or more.

5. The display device of claim 1, wherein the first polarizing film and the second polarizing film comprise linear polarizing films, and
wherein a first polarization axis of the first polarizing film and a second polarization axis of the second polarizing film are substantially perpendicular.

6. The display device of claim 5, wherein the first polarizing film comprises an absorption type polarizing film, and
wherein the second polarizing film comprises a reflective polarizing film.

7. The display device of claim 5, further comprising a third polarizing film above the second lens and having a third polarization axis extending in a direction parallel to the second polarization axis.

8. The display device of claim 7, wherein the third polarizing film comprises an absorption type polarizing film.

9. The display device of claim 1, wherein the first phase retardation film and the second phase retardation film comprise a quarter-wave plate, and
wherein a first optical axis of the first phase retardation film and a second optical axis of the second phase retardation film are offset in opposite directions.

10. The display device of claim 1, wherein the first lens and the second lens comprise magnifying lenses.

11. The display device of claim 1, wherein the semi-transmissive reflective film comprises layers in which first material layers having a first refractive index and second material layers, which have a second refractive index that is greater than the first refractive index, are alternately stacked, and
wherein a lowermost layer of the first and second material layers is one of the first material layers.

12. The display device of claim 11, wherein a number of the first material layers is greater than a number of the second material layers.

13. The display device of claim 12, wherein the number of the first material layers is greater than the number of the second material layers by one.

14. The display device of claim 11, wherein the first material layers comprise silicon oxide, and
wherein the second material layers comprise titanium oxide.

15. The display device of claim 11, wherein a number of the first and second layers is nine or more.

16. The display device of claim 11, wherein the first refractive index is about 1.91 to about 1.93, and
wherein the second refractive index is about 3.45 to about 3.47.

17. The display device of claim 1, wherein the window module and the first optical module are spaced apart, and
wherein the first optical module and the second optical module are spaced apart.

18. The display device of claim 1, further comprising a coating film on a surface of the first optical module or a surface of the second optical module.

19. The display device of claim 1, further comprising a third phase retardation film between the display module and the first polarizing film and comprising a quarter-wave plate.

20. The display device of claim 1, wherein the display panel further comprises:
a semiconductor substrate;
conductive layers sequentially stacked above the semiconductor substrate;
a reflective electrode layer above the conductive layers;
an insulating film covering at least a part of the reflective electrode layer; and
light-emitting elements above the insulating film, and comprising a first electrode, a light-emitting stack, and a second electrode.

21. An electronic device comprise a display device, the display device comprising:
a display panel comprising a display module, and a window module above the display module and comprising:
a first polarizing film above the display module;
a first phase retardation film above the first polarizing film;
a window above the first phase retardation film; and
a semi-transmissive reflective film above the window; and
an optical module above the display panel, and comprising:
a first optical module comprising a first lens above the semi-transmissive reflective film; and
a second optical module comprising a second phase retardation film above the first lens, a second polarizing film above the second phase retardation film, and a second lens above the second polarizing film.
